(19) United States
(12) Patent Application Publication
(10) Pub. No.: US 2025/0072186 A1
(43) Pub. Date: Feb. 27, 2025

(54) MULTILAYER STRUCTURE, PACKAGE COMPONENT AND OPTICAL SEMICONDUCTOR DEVICE

(71) Applicant: Panasonic Holdings Corporation, Osaka (JP)

(72) Inventors: Takahiro FUKUNAGA, Kyoto (JP); Tomohiro FUTAGAMI, Kyoto (JP); Yoshihide OOMURA, Kyoto (JP)

(21) Appl. No.: 18/726,377

(22) PCT Filed: Dec. 5, 2022
(86) PCT No.: PCT/JP2022/044729

§ 371 Date: Jul. 2, 2024

(30) Foreign Application Priority Data
Jan. 13, 2022 (JP) 2022-003772

(51) Int. Cl. H01L 33/62; C09D 177/00; H01L 33/48; H01L 33/60

(52) U.S. Cl. CPC H01L 33/62; C09D 177/00; H01L 33/483; H01L 33/60; H01L 2933/0058; H01L 2933/0066

(57) ABSTRACT

A circuit substrate includes: a first metal that has a first standard electrode potential; a second metal that is stacked on the upper surface of the first metal and has a second standard electrode potential higher than the first standard electrode potential; and a coating that coats the upper surface of the second metal and includes a functional organic molecule. The functional organic molecule includes a first molecular skeleton that includes: a first bond portion in which a sulfur atom having a negative oxidation number is bonded to a carbon atom; and a second bond portion in which a nitrogen atom having a negative oxidation number is bonded to the carbon atom. In the coating, the first molecular skeleton has tautomerism where a first structure in which the nitrogen atom is bonded to a hydrogen atom and a second structure in which the sulfur atom is bonded to the hydrogen atom are isomerized to each other.

### CROSS-REFERENCE OF RELATED APPLICATIONS

This application is the U.S. National Phase under 35 U.S.C. § 371 of International Patent Application No. PCT/JP2022/044729, filed on Dec. 5, 2022, which in turn claims the benefit of Japanese Patent Application No. 2022-003772, filed on Jan. 13, 2022, the entire disclosure of which Applications are incorporated by reference herein.

### TECHNICAL FIELD

The present invention relates to a multilayer structure, an optical semiconductor device package component which uses a multilayer structure, and an optical semiconductor device, and particularly relates to a technique which suppresses deterioration of an optical semiconductor device when the optical semiconductor device is used for a long period of time.

### BACKGROUND ART

In a conventional optical semiconductor device package component, for example, a silver coating is formed as a reflective coating on the outermost layer (that is, the bottom surface of a recess on which an optical semiconductor element is mounted) of a region surrounded by a surrounding resin (hereinafter also referred to as an “optical semiconductor element mounting region”). This region serves to efficiently reflect light to the outside of the optical semiconductor device package component to enhance the efficiency of light emission.

In the present specification, an optical semiconductor such as a light emitting element or a light receiving element is referred to as an optical semiconductor element, a package component itself for mounting an optical semiconductor element is referred to as an optical semiconductor device package component, and an entire optical semiconductor device package component on which an optical semiconductor element is mounted (which is a combination of the optical semiconductor element and the optical semiconductor device package component) is referred to as an optical semiconductor device.

As the layer configuration of a silver coating in an optical semiconductor device package component, silver plating is often formed on copper or a copper alloy (see, for example, Patent Literature (PTL) 1). Disadvantageously, however, in the silver plating of such a layer structure, copper serving as a base metal diffuses to the surface of the silver plating due to the influence of heat generated by long-term use of an optical semiconductor device, and thus the surface of the silver plating is discolored to a copper color, with the result that a decrease in reflectance is caused.

On the other hand, as a method for preventing the disadvantage described above, a method is provided in which nickel plating is applied on top of copper or a copper alloy as a barrier layer for preventing diffusion of copper, palladium plating is applied on top thereof to prevent diffusion of a sulfur brightener in the nickel plating, and silver plating is applied on top thereof (see, for example, PTL 2).

FIG. 1 is a cross-sectional view showing the configuration of conventional optical semiconductor device package component 50 which uses nickel and palladium as a barrier layer for preventing diffusion of copper.

As in FIG. 1, in circuit substrate 54 serving as a lead frame in optical semiconductor device package component 50, for example, on substantially the entire surface of a metal base member formed of copper or copper alloy 51, base plating formed of nickel plating 52a and palladium plating 52b and a reflective layer formed of silver or silver alloy 53 are stacked in this order. The internal space of optical semiconductor device package component 50 is filled with a sealing resin after die bonding and wire bonding are performed on a predetermined optical semiconductor element.

In the layer configuration of the optical semiconductor device package component as described above, it is possible to prevent a decrease in reflectance caused by diffusion of base copper to the surface of a silver coating due to the long-term thermal history of an optical semiconductor device.

Disadvantageously, however, when the optical semiconductor device is driven for a long period of time, light emitted from the optical semiconductor element is applied to titanium oxide which is a white pigment included in a surrounding resin that functions as a reflector (that is, a reflecting member), and thus active oxygen (specifically, a superoxide anion) generated when titanium oxide is excited to exhibit photocatalytic action turns silver into silver oxide to turn its color black, with the result that the life of the optical semiconductor device is further shortened.

As a countermeasure against the blackening of silver caused by the active oxygen described above, a technique is proposed in PTL 3 in which a metal having a standard electrode potential higher than silver and a metal having a standard electrode potential lower than silver are formed on a silver base, and thus both a decrease in the reflectance of a reflective coating caused by discoloration of silver plating due to diffusion of base copper and blackening of silver caused by active oxygen generated by photocatalytic action of titanium oxide in a surrounding resin induced by long-term driving.

### CITATION LIST

### Patent Literature

[PTL 1] Japanese Unexamined Patent Application Publication No. 2013-171969
[PTL 2] Japanese Unexamined Patent Application Publication No. 2007-258514
[PTL 3] International Publication No. 2019/082480

### SUMMARY OF INVENTION

### Technical Problem

However, the following issues exist in an optical semiconductor device and the like.

In the case of a metal coating including a silver coating in the layer configuration of a circuit substrate serving as a multilayer structure and an optical semiconductor device package component as disclosed in PTL 3, it is possible to suppress the blackening of silver caused by active oxygen by the sacrificial corrosion effect of a metal having a standard electrode potential lower than silver. However, for example, when a large amount of active oxygen is generated by driving an optical semiconductor device for a longer period of time and/or driving it at a higher output than a conventionally case, another problem occurs in which the metal having a standard electrode potential lower than silver is completely oxidized, thus the sacrificial corrosion effect is lowered, and consequently, the effect of suppressing the blackening of silver caused by active oxygen is lowered.

Disadvantageously, in an electronic component using a circuit substrate whose surface is covered with silver, an optical semiconductor device package component, and the like, depending on a storage environment, the electronic component is exposed to trace amounts of active oxygen present in the atmosphere (for example, a superoxide anion, a hydroxyl radical, hydrogen peroxide, chlorine dioxide, and the like) during long-term storage, thus the surface of silver is gradually oxidized to turn black, and consequently, the efficiency of light emission is lowered due to a decrease in reflectance. Even in a circuit substrate whose surface is covered with a metal other than silver, an optical semiconductor device package component, and the like, the metal on the surface is oxidized by active oxygen, and thus deterioration as such discoloration, alteration, and embrittlement of the metal on the surface occurs, with the result that an electronic component using the circuit substrate, the optical semiconductor device package component, and the like cannot achieve their initial performance, and in some cases, the electronic component is not operated.

The present invention is made in view of the foregoing issues, and provides a multilayer structure, a package component, and an optical semiconductor device which can effectively suppress shortening of the life of an electronic component caused by deterioration of a metal on the surface due to active oxygen induced by long-term driving of the electronic component such as an optical semiconductor device and active oxygen present in the atmosphere.

### Solution to Problem

A multilayer structure according to an aspect of the present invention includes: a first metal that has a first standard electrode potential; a second metal that is stacked on an upper surface of the first metal and has a second standard electrode potential higher than the first standard electrode potential; and a coating that coats an upper surface of the second metal and includes a functional organic molecule, the functional organic molecule includes a first molecular skeleton that includes: a first bond portion in which a sulfur atom having a negative oxidation number is bonded to a carbon atom; and a second bond portion in which a nitrogen atom having a negative oxidation number is bonded to a carbon atom, and in the coating, the first molecular skeleton has tautomerism where a first structure in which the nitrogen atom is bonded to a hydrogen atom and a second structure in which the sulfur atom is bonded to a hydrogen atom are isomerized to each other by addition and removal of a hydrogen atom.

A package component according to an aspect of the present invention is a package component for mounting an optical semiconductor element, the package component includes: a circuit substrate; and a wall that is disposed on the circuit substrate, surrounds an outer periphery of a region on the circuit substrate on which the optical semiconductor element is mounted, and includes a white pigment, the circuit substrate is the multilayer structure. An optical semiconductor device according to an aspect of the present invention includes: an optical semiconductor element; and the package component on which the optical semiconductor element is mounted.

### Advantageous Effects of Invention

In the multilayer structure, the package component, and the optical semiconductor device according to the aspects of the present invention, it is possible to effectively suppress a decrease in the performance of an electronic component caused by deterioration of a metal on the surface due to active oxygen induced by long-term driving of the electronic component such as an optical semiconductor device and active oxygen present in the atmosphere.

### BRIEF DESCRIPTION OF DRAWINGS

FIG. 1 is a cross-sectional view showing the configuration of a conventional optical semiconductor device package component.

FIG. 2A is a cross-sectional view showing the configuration of an optical semiconductor device package component according to an embodiment.

FIG. 2B is an enlarged view of region IIb in FIG. 2A.

FIG. 2C is an enlarged view of region IIc in FIG. 2B.

FIG. 2D is a diagram for illustrating tautomerism of a first molecular skeleton in a functional organic molecule in the embodiment.

FIG. 3 is a cross-sectional view showing the configuration of an optical semiconductor device according to the embodiment.

FIG. 4 is a diagram for illustrating suppression of shortening of the life of the optical semiconductor device according to the embodiment.

FIG. 5 is a diagram for illustrating action for scavenging the radical of active oxygen caused by the first molecular skeleton in the functional organic molecule in the embodiment.

FIG. 6 is a diagram for illustrating inactivation of active oxygen caused by a coating and a metal film in the embodiment.

FIG. 7 is a diagram for comparing the forms of existence of sulfur atoms on a second metal.

FIG. 8 is a diagram showing a manufacturing process for the optical semiconductor device package component according to the embodiment.

FIG. 9 is a diagram showing a manufacturing process for a composite film in the optical semiconductor device package component according to the embodiment.

FIG. 10 is a diagram showing a manufacturing process for another composite film in the optical semiconductor device package component according to the embodiment.

FIG. 11 is a flowchart of a step of forming the coating including the functional organic molecule in the embodiment.

FIG. 12 is a diagram for illustrating the step of forming the coating including the functional organic molecule in the embodiment.

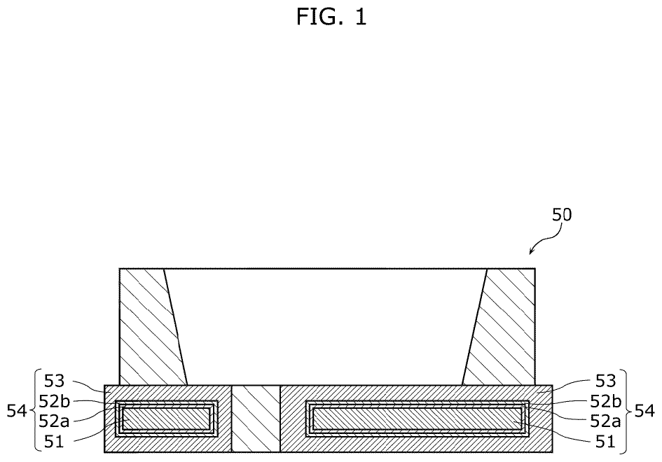

### DESCRIPTION OF EMBODIMENTS

Embodiments of the present invention will be described below with reference to accompanying drawings. Naturally, the present invention is not limited to these embodiments, and can be changed as necessary and implemented without departing from the technical range of the present invention. In other words, each of the embodiments which will be describe below shows a specific example of the present invention. Numerical values, shapes, materials, constituent elements, the arrangement and connection of the constituent elements, steps, the order of the steps, and the like shown in the following embodiments are examples, and are not intended to limit the present invention. Among the constituent elements in the following embodiments, constituent elements which are not recited in the independent claim are described as optional constituent elements. The drawings are schematic views, and are not exactly shown. For example, in the drawings, in order to easily see the configuration of layers, lengths in a thickness direction may be exaggerated. In the drawings, substantially the same configurations are identified with the same reference signs, and repeated description is omitted or simplified.

In the present specification, terms which indicate relationships between elements, terms which indicate the shapes of the elements, and the ranges of numerical values are expressions which indicate not only exact meanings but also substantially equivalent ranges such as a range including about a several percent difference.

In the present specification, the terms “upward” and “downward” do not indicate an upward direction (vertically upward) and a downward direction (vertically downward) in absolute spatial recognition but are used as terms which are defined by a relative positional relationship based on the order of layers stacked in a multilayer configuration. Specifically, the side of light emission or light reception when an optical semiconductor device package component is used in an optical semiconductor device is assumed to be “upward”. The terms such as “upward” and “downward” are only used to specify the mutual arrangement of members, and are not intended to limit the posture of the optical semiconductor device package component when the optical semiconductor device package component is used. The terms “upward” and “downward” are applied not only to a case where two constituent elements are spaced with another constituent element present between the two constituent elements but also to a case where two constituent elements are arranged in close contact with each other.

### Embodiment

An optical semiconductor device package component which includes a circuit substrate according to an embodiment and an optical semiconductor device which uses the optical semiconductor device package component will be described below.

### [1. Configuration]

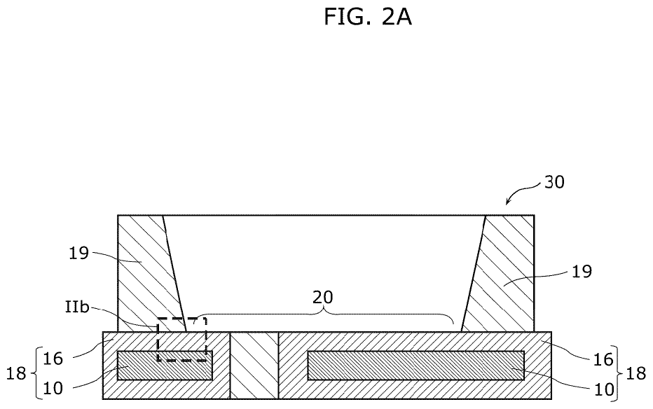

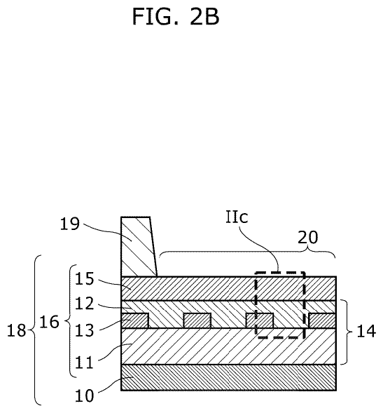

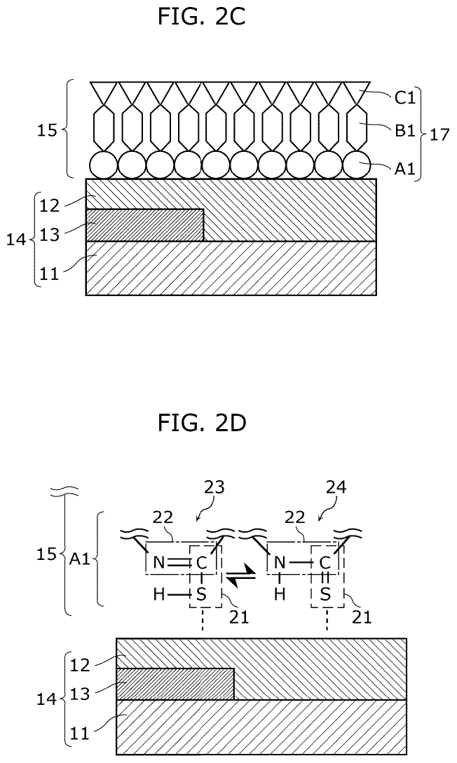

The configuration of the optical semiconductor device package component which includes the circuit substrate according to the present embodiment will first be described with reference to FIGS. 2A to 2D. FIG. 2A is a cross-sectional view showing the configuration of optical semiconductor device package component 30 according to the present embodiment. FIG. 2B is an enlarged view of region IIb in FIG. 2A. FIG. 2C is an enlarged view of region IIc in FIG. 2B. FIG. 2D is a diagram for illustrating tautomerism of first molecular skeleton A1 in functional organic molecule 17. Although optical semiconductor device package component 30 according to the present embodiment is a package component suitable for mounting an optical semiconductor element, the element to be mounted is not limited to an optical semiconductor element and may be a normal semiconductor element. In other words, optical semiconductor device package component 30 according to the present embodiment is an example of a package component which can also be called a “semiconductor device package component”. Optical semiconductor device package component 30 as a whole includes a structure in the shape of a rectangular parallelepiped, and a recess for mounting an optical semiconductor element is formed.

Optical semiconductor device package component 30 according to the present embodiment is formed, for example, by processing a metal base member formed of copper, iron, nickel, or an alloy including at least two thereof into a desired shape by a molding technique such as pressing or etching, and performing predetermined surface treatment and resin molding on a surrounding resin including a white pigment. More specifically, as shown in FIG. 2A, optical semiconductor device package component 30 according to the present embodiment is a package component for mounting an optical semiconductor element, and includes circuit substrate 18 serving as a lead frame and surrounding resin 19 which is formed on circuit substrate 18 and surrounds the outer periphery of a region (specifically, optical semiconductor element mounting region 20 shown in FIGS. 2A and 2B) on circuit substrate 18 on which the optical semiconductor element is mounted. Circuit substrate 18 is an example of a multilayer structure. Surrounding resin 19 is an example of a wall which includes the white pigment.

As shown in FIGS. 2A to 2C, circuit substrate 18 includes base member 10 and composite film 16 which is formed on base member 10 and has a multilayer structure. Composite film 16 includes metal film 14 which is formed on base member 10 and has a multilayer structure and coating 15 which coats the upper surface of metal film 14 and includes functional organic molecule 17. In composite film 16 which is shown in FIGS. 2A and FIGS. 3, 4, and 8 to be described later and has not been enlarged, the multilayer structure of composite film 16 is omitted.

Metal film 14 of the multilayer structure includes: first metal 11 which is stacked on base member 10 and has a first standard electrode potential; second metal 12 which is stacked on the upper surface of first metal 11 and has a second standard electrode potential higher than the first standard electrode potential; and third metal 13 which is formed on parts of the upper surface of first metal 11 and has a third standard electrode potential higher than the first standard electrode potential and the second standard electrode potential. Coating 15 coats the upper surface of second metal 12.

In an example shown in FIG. 2A, composite film 16 is formed to cover all the surfaces of base member 10. Although FIG. 2B shows the stacking structure of composite film 16 formed on the upper surface of base member 10, for example, composite film 16 which is formed on all the lower surface and the side surfaces of base member 10 also has the same stacking structure as the structure shown in FIG. 2B. For example, first metal 11 is formed on all the surfaces of base member 10. Third metal 13 is formed on parts of the entire surface (that is, the outer surface) of first metal 11 on a side opposite to the side of base member 10. Second metal 12 is formed to cover all the exposed surfaces of first metal 11 and third metal 13. The exposed surfaces of first metal 11 are surfaces of the surface (that is, the outer surface) of first metal 11 on the side opposite to the side of base member 10 on which third metal 13 is not formed. The exposed surfaces of third metal 13 are, for example, surfaces other than the surfaces of third metal 13 on the side of first metal 11. Coating 15 coats, for example, the entire surface (that is, the outer surface) of second metal 12 on a side opposite to the side of first metal 11.

Circuit substrate 18 is formed with a pair of circuit substrates which are separate from each other (in FIG. 2A, separate in a left/right direction). The pair of circuit substrates 18 are disposed on the same plane and has the same stacking structure.

In the configuration of the present embodiment, for example, in optical semiconductor element mounting region 20 on which a semiconductor element or an optical semiconductor element (not shown) is mounted, on the outermost surface of metal film 14 in circuit substrate 18, silver or a silver-containing alloy plating layer that is an example of second metal 12 for enhancing the reflectance of light is formed.

As a more specific example, as shown in FIG. 2B, in optical semiconductor element mounting region 20, in circuit substrate 18 serving as the lead frame, on at least a part of the upper surface of base member 10 including copper or a copper alloy that is an example of the metal base member, nickel or a nickel alloy that is an example of first metal 11 is formed as a barrier layer for suppressing diffusion of copper, and on the upper surface of first metal 11, silver or a silver alloy that is an example of second metal 12 serving as a reflective layer is stacked. On a part of the surface of second metal 12, bowl-shaped surrounding resin 19 is formed as the wall, and the surrounding resin 19 serves as a reflector (that is, a reflecting member) which reflects light emitted by the mounted optical semiconductor element toward the outside (upward in FIG. 2A and the like) via coating 15.

Furthermore, third metal 13 is formed between first metal 11 and second metal 12 in a stacking direction. First metal 11 may also be formed below surrounding resin 19 serving as the wall.

The constituent elements of optical semiconductor device package component 30 including circuit substrate 18 according to the present embodiment will be described in detail below.

### [1-1. Base Member]

Base member 10 serves as the metal base member of the lead frame. Base member 10 is, for example, the base member of copper or a copper alloy which is conductive. On the upper surface of the base member of copper or a copper alloy which is an example of base member 10, copper strike plating or copper plating may be applied. As base member 10, instead of the base member of copper or a copper alloy, iron, an iron-nickel alloy, a stainless steel member or an aluminum member may be used as the metal base member. The standard electrode potential of base member 10 is, for example, lower than the second standard electrode potential.

As base member 10, an insulating base member may be used. Examples of the insulating base member which can be used include a glass epoxy resin, ceramics, quartz, glass, translucent resin and the like.

### [1-2. First Metal]

First metal 11 serves as a barrier layer for suppressing diffusion of metal which suppresses diffusion of the metal from base member 10. First metal 11 is also in contact with the surface of base member 10 to function as a layer for enhancing adhesion to base member 10. First metal 11 is a metal which has the first standard electrode potential. First metal 11 is, for example, a plating layer of nickel or a nickel alloy. In this way, even when the optical semiconductor device is driven for a long period of time, since first metal 11 is present on the base of second metal 12 (for example, silver or a silver alloy) in optical semiconductor element mounting region 20, even in a case where base member 10 is copper or a copper alloy, it is possible to suppress a decrease in reflectance caused by diffusion of a large amount of copper or a copper alloy to the surface of second metal 12 (that is, a reflective coating). In particular, nickel or a nickel alloy is useful for suppressing diffusion of the metal of base member 10.

The thickness of first metal 11 is, for example, greater than or equal to 0.05 μm and less than or equal to 10 μm, and may be greater than or equal to 0.2 μm and less than or equal to 1.0 μm. The thickness of first metal 11 is greater than or equal to 0.05 μm, and thus it is possible to effectively suppress diffusion of the metal such as copper or a copper alloy which serves as the base member. The thickness of first metal 11 is less than or equal to 10 μm, and thus a crack is unlikely to occur even when bending stress is applied.

First metal 11 is not limited to the example where first metal 11 includes nickel or a nickel alloy, first metal 11 may include titanium, chromium, zinc, aluminum, or the like, and first metal 11 can be selected depending on the type of base member 10. For example, first metal 11 may be a metal different from base member 10, may be specifically a metal other than copper or a copper alloy or may be a metal which is more unlikely to be diffused to second metal 12 than copper or a copper alloy.

A configuration may be adopted in which circuit substrate 18 does not include base member 10, and the region of base member 10 in circuit substrate 18 is occupied by first metal 11. In this case, first metal 11 may serve as the metal base member of base member 10 described previously.

### [1-3. Second Metal]

Second metal 12 serves as the reflective layer which reflects light entering optical semiconductor element mounting region 20. Second metal 12 is stacked on the upper surface of first metal 11. Second metal 12 is in contact with regions of the surface of first metal 11 on the side opposite to base member 10 where third metal 13 is not formed. Second metal 12 is a metal which has the second standard electrode potential higher than the first standard electrode potential and lower than the third standard electrode potential. Second metal 12 is, for example, a plating layer which includes silver or a silver alloy. In this way, it is possible to form the reflective layer which has a high reflectance and excellent electrical conductivity.

The plating layer of silver or a silver alloy which is an example of second metal 12 may function not only as an optical reflective portion (that is, a reflective coating) but also as die bonding, wire bonding, or flip chip bonding for connection to the optical semiconductor element to be mounted or wiring capable of being soldered. The thickness of second metal 12 is, for example, greater than or equal to 0.001 μm and less than or equal to 6 μm, and may be greater than or equal to 0.05 μm and less than or equal to 3 μm. The thickness of second metal 12 is greater than or equal to 0.001 μm, and thus light is unlikely to pass through second metal 12, with the result that the reflectance is enhanced. The thickness of second metal 12 is less than or equal to 6 μm, thus the amount of second metal 12 used is reduced, and second metal 12 includes silver or the like which is a noble metal having a high standard electrode potential, with the result that manufacturing costs can be lowered.

In particular, in a case where importance is placed on enhancing wire bondability when third metal 13 is formed, the thickness of second metal 12 may be greater than or equal to 0.01 μm and less than or equal to 0.2 μm. In this way, during ultrasonic bonding, the wire of a wire bonding metal such as gold or silver easily breaks through second metal 12, and thus first metal 11 (for example, nickel) and third metal 13 (for example, palladium) can be simultaneously bonded together with second metal 12 (for example, silver), with the result that the effect of increasing bonding strength (pull strength) is obtained. Furthermore, the amount of second metal 12 such as silver used can be reduced, and this leads to conservation of resources of noble metals.

Second metal 12 (for example, silver or a silver alloy) and first metal 11 (for example, nickel or a nickel alloy) are in direct contact with each other, and thus it is possible to suppress shortening of the life of the optical semiconductor device for the following reasons: by the influence of photocatalytic action caused by “heat”, “light”, and “titanium oxide serving as the white pigment in surrounding resin 19 which functions as the reflector” when the optical semiconductor device is driven for a long period of time, oxygen present in the atmosphere is turned into active oxygen (specifically, a superoxide anion), and the active oxygen turns silver which is an example of second metal 12 into silver oxide to turn its color black. Specifically, first metal 11 (for example, nickel or a nickel alloy) which has a standard electrode potential lower than second metal 12 (for example, silver or a silver alloy) is in contact with second metal 12. Hence, active oxygen which permeates second metal 12 reacts with first metal 11, and thus the blackening of sliver which is an example of second metal 12 is suppressed by a sacrificial corrosion effect caused by corrosion of first metal 11. The details of the effect will be described later. In addition to the blackening, it is also possible to suppress deterioration cause by oxidation of second metal 12.

### [1-4. Third Metal]

Third metal 13 serves as an electron-attracting layer which attracts electrons from second metal 12. Third metal 13 is formed on parts of the upper surface of first metal 11 and parts of the lower surface of second metal 12. Third metal 13 is in contact with first metal 11 and second metal 12. Third metal 13 is a metal which has the third standard electrode potential higher than the first standard electrode potential and lower than the second standard electrode potential. Third metal 13 is, for example, a plating layer which includes gold, a gold alloy, or a platinum group element-containing metal. The platinum group element-containing metal is, for example, palladium, a palladium alloy, platinum, a platinum alloy, rhodium, a rhodium alloy, ruthenium or a ruthenium alloy, and may be palladium, a palladium alloy, platinum, or a platinum alloy among them.

Since palladium has a good affinity with silver and nickel, the plating layer of palladium or a palladium alloy which is an example of third metal 13 also functions as a layer for enhancing adhesion to the plating layer of silver which is an example of second metal 12 and the plating layer of nickel which is an example of first metal 11.

Third metal 13 is present, and thus it is possible to suppress shortening of the life of the optical semiconductor device, for example, for the following reasons: by the influence of photocatalytic action caused by “heat”, “light”, and “titanium oxide serving as the white pigment in surrounding resin 19 which functions as the reflector” when the optical semiconductor device is driven for a long period of time, oxygen present in the atmosphere is turned into active oxygen (specifically, a superoxide anion), and the active oxygen turns silver into silver oxide to turn its color black. Specifically, third metal 13 (for example, palladium or a palladium alloy) having the third standard electrode potential plays a role in attracting electrons which excessively enter second metal 12 (for example, silver or a silver alloy) having the second standard electrode potential and transmitting them to first metal 11 (for example, nickel or a nickel alloy). Hence, electron circulation is formed in which excessive electrons in second metal 12 generated when first metal 11 donates electrons to second metal 12 by the sacrificial corrosion action are transmitted to third metal 13, and are returned to first metal 11. In this way, the blackening of silver which is an example of second metal 12 caused by active oxygen is suppressed, and thus it is possible to suppress the oxidation progress of first metal 11 caused by the sacrificial corrosion effect of first metal 11 while suppressing a decrease in reflectance. The details of the effect will be described later.

The thickness of third metal 13 is, for example, greater than or equal to 0.0002 μm and less than or equal to 0.06 μm, and may be greater than or equal to 0.001 μm and less than or equal to 0.01 μm. Third metal 13 is present on first metal 11, and thus the oxidation of the surface of first metal 11 caused by oxygen permeating the second metal when first metal 11 is heated to a high temperature is suppressed, with the result that heat-resistant adhesion to first metal 11 and second metal 12 is enhanced. However, if third metal 13 completely covers first metal 11, first metal 11 is not in direct contact with second metal 12, and thus the sacrificial corrosion effect caused by first metal 11 cannot be achieved. Hence, in the present embodiment, third metal 13 does not completely cover first metal 11, and covers only parts. In other words, third metal 13 is formed on parts of the upper surface of first metal 11. Although the shape of third metal 13 when viewed from above is not particularly limited, for example, third metal 13 is in the shape of stripes, dots, a grid, or a combination of two or more of these shapes. The area of an interface between first metal 11 and third metal 13 is, for example, greater than zero, and less than the area of an interface between first metal 11 and second metal 12.

### [1-5. Coating Including Functional Organic Molecule]

Coating 15 which includes functional organic molecule 17 is an organic coating which is formed on the upper surface of second metal 12 by self-assembly of functional organic molecule 17. Coating 15 includes functional organic molecules 17 in which molecular chains are aligned in the same direction on the upper surface of second metal 12.

As shown in FIG. 2C, functional organic molecule 17 includes first molecular skeleton A1, main chain B1, and second molecular skeleton C1. Functional organic molecule 17 is formed by bonding first molecular skeleton A1, main chain B1, and second molecular skeleton C1 in this order. For example, first molecular skeleton A1 is bonded to the side of one end of main chain B1 (for example, is covalently bonded thereto). Second molecular skeleton C1 is bonded to the side of the other end of main chain B1 (for example, is covalently bonded thereto).

Functional organic molecule 17 is not limited to an example shown in FIG. 2C, and may be an organic molecule which includes at least first molecular skeleton A1. For example, functional organic molecule 17 may be an organic molecule formed with only first molecular skeleton A1, may be an organic molecule formed by bonding first molecular skeleton A1 and main chain B1, or may be an organic molecule formed by bonding first molecular skeleton A1 and second molecular skeleton C1. Functional organic molecule 17 is synthesized using various organic synthesis methods. The details of constituent elements of functional organic molecule 17 will be described below.

### [1-5-1. First Molecular Skeleton A1]

First molecular skeleton A1 is a functional portion which includes a compound, a chemical structure, or a derivative that contains one or more of functional groups exhibiting a metal binding property. As shown in FIG. 2D, first molecular skeleton A1 includes one or more groups of first bond portion 21 and second bond portion 22. First bond portion 21 has a bond structure in which a sulfur atom having a negative oxidation number is bonded to a carbon atom (specifically, is covalently bonded thereto). Second bond portion 22 has a bond structure in which a nitrogen atom having a negative oxidation number is bonded to the carbon atom (specifically, is covalently bonded thereto). Each of the sulfur atom in first bond portion 21 and the nitrogen atom in second bond portion 22 includes an unshared electron pair. For example, the sulfur atom in first bond portion 21 and the nitrogen atom in second bond portion 22 are bonded to the same carbon atom. In other words, first bond portion 21 and second bond portion 22 share, for example, one carbon atom.

As shown in FIG. 2D, in coating 15, first molecular skeleton A1 has tautomerism where first structure 24 in which the nitrogen atom in second bond portion 22 has a bond (specifically, a covalent bond) to a hydrogen atom and second structure 23 in which the sulfur atom in first bond portion 21 has a bond (specifically, a covalent bond) to the hydrogen atom are isomerized to each other by addition and removal of the hydrogen atom. Specifically, in first structure 24, the hydrogen atom is added to the sulfur atom in first bond portion 21, the hydrogen atom bonded to the nitrogen atom in second bond portion 22 is removed, and thus first structure 24 is isomerized to second structure 23. In second structure 23, the hydrogen atom bonded to the sulfur atom in first bond portion 21 is removed, the hydrogen atom is added to the nitrogen atom in second bond portion 22, and thus second structure 23 is isomerized to first structure 24.

For example, in first structure 24, the hydrogen atom is not bonded to the sulfur atom in first bond portion 21, and in second structure 23, the hydrogen atom is not bonded to the nitrogen atom in second bond portion.

First structure 24 includes, for example, a structure (for example, a thiocarbonyl group) in which the sulfur atom and the carbon atom in first bond portion 21 are double bonded, and a structure (for example, a secondary amine) in which the nitrogen atom and the carbon atom in second bond portion 22 are single bonded. Second structure 23 includes a structure (for example, a thiol group) in which the sulfur atom and the carbon atom in first bond portion 21 are single bonded, and a structure (for example, an imine group) in which the nitrogen atom and the carbon atom in second bond portion 22 are double bonded.

For example, the sulfur atom in first bond portion 21 is disposed on second metal 12 without the intervention of another atom. For example, the sulfur atom in first bond portion 21 has an interaction with second metal 12 such as a coordination bond to second metal 12.

In first structure 24, the sulfur atom in first bond portion 21 has a negative oxidation number and a high electron density to have nucleophilicity, and thus electron transfer easily occurs between the sulfur atom and the carbon atom in first bond portion 21, with the result that the hydrogen atom (proton) is easily added to the sulfur atom. Hence, the hydrogen atom is bonded to the sulfur atom in first bond portion 21, and thus first structure 24 can be isomerized to second structure 23.

The oxidation number of the sulfur atom in first bond portion 21 is, for example, —2. In this way, it is possible to easily form first molecular skeleton A1 which has tautomerism.

On the other hand, when the oxidation number of the sulfur atom in first bond portion 21 is greater than or equal to zero, for example, when the sulfur atom is bonded to an oxygen atom or a chlorine atom or a halogen atom such as a fluorine atom, the electron density of the sulfur atom is lowered, and thus it is difficult to achieve isomerization between first structure 24 and second structure 23.

In second structure 23, the nitrogen atom in second bond portion 22 has a negative oxidation number and a high electron density to have nucleophilicity, and thus electron transfer easily occurs between the nitrogen atom and the carbon atom in second bond portion 22, with the result that the hydrogen atom (proton) is easily added.

The oxidation number of the nitrogen atom in second bond portion 22 is, for example, —3. In this way, it is possible to easily form first molecular skeleton A1 which has tautomerism.

On the other hand, when the oxidation number of the nitrogen atom is greater than or equal to zero, for example, when the nitrogen atom is bonded to an oxygen atom, the electron density of the nitrogen atom is lowered, and thus it is difficult to achieve isomerization between first structure 24 and second structure 23.

As described above, first bond portion 21 and second bond portion 22 are present in the molecular structure of first molecular skeleton A1, and thus on second metal 12, transfer of a π electron is possible between the sulfur atom in first bond portion 21 and the nitrogen atom in second bond portion 22 via the carbon atom. Furthermore, the hydrogen atom can be removed and added from and to the sulfur atom in first bond portion 21 or the nitrogen atom in second bond portion 22. Hence, first molecular skeleton A1 can take a structure which has tautomerism.

First molecular skeleton A1 is required to have, for example, the property of a high affinity for metal materials, a metal bonding property caused by a bond such as a hydrogen bond or a coordinate bond, and the property of tautomerism described above. As long as first molecular skeleton A1 has these properties, first molecular skeleton A1 may be any one of a compound, a chemical structure, and a derivative that includes one or more of functional groups.

First molecular skeleton A1 includes, for example, a nitrogen-containing heterocycle that includes first bond portion 21 in which the sulfur atom and the carbon atom are bonded and second bond portion 22 in which the nitrogen atom and the carbon atom are bonded. The nitrogen-containing heterocycle includes the nitrogen atom in second bond portion 22 as the nitrogen atom of the nitrogen-containing heterocycle. As described above, since first molecular skeleton A1 includes the nitrogen-containing heterocycle, an affinity between first molecular skeletons A1 is enhanced, and thus first molecular skeletons A1 are easily arranged on second metal 12, with the result that it is possible to form highly stable coating 15.

Examples of the nitrogen-containing heterocycle include an imidazole skeleton, a benzimidazole skeleton, a triazole skeleton, a tetrazole skeleton, a thiazole skeleton, a benzothiazole skeleton, a thiadiazole skeleton, an oxazole skeleton, a benzoxazole skeleton, an oxadiazole skeleton, a pyridine skeleton, a pyrimidine skeleton, a pyrazine skeleton, a pyridazine skeleton, a triazine skeleton, a purine skeleton, and the like.

First molecular skeleton A1 may include two or more first bond portions 21 and two or more second bond portions 22. In this way, by the sulfur atoms in first bond portions 21, functional organic molecules 17 are more firmly bonded to second metal 12, and thus the thermal stability of coating 15 is enhanced.

Here, the detailed molecular structure of first molecular skeleton A1 will be described using the molecular skeleton of first structure 24 as an example.

As shown in FIG. 2D, first structure 24 in first molecular skeleton A1 includes, for example, the thiocarbonyl group which includes the sulfur atom in first bond portion 21. The thiocarbonyl group is changed into the thiol group in second structure 23. As shown in FIG. 2D, first structure 24 in first molecular skeleton A1 includes the secondary amine which includes the nitrogen atom in second bond portion 22. The secondary amine is changed into the imine group in second structure 23. In these structures, with the hydrogen atom bonded to the nitrogen atom in second bond portion 22, the sulfur atom of the thiocarbonyl group is coordinated to a metal atom such as gold or silver capable of becoming a cation of one or more valences or to nickel (Ni), copper (Cu) or the like, and first molecular skeleton A1 is attached to second metal 12. The secondary amine can capture active oxygen and then inactivate the captured active oxygen. The details of the effect of first molecular skeleton A1 will be described later. For example, coating 15 includes at least functional organic molecule 17 in a state where first molecular skeleton A1 has first structure 24.

More specifically, for example, first structure 24 includes: (i) one or more selected from a group consisting of an imidazole skeleton, a benzimidazole skeleton, a triazole skeleton, a tetrazole skeleton, a thiazole skeleton, a benzothiazole skeleton, a thiadiazole skeleton, an oxazole skeleton, a benzoxazole skeleton, an oxadiazole skeleton, a pyridine skeleton, a pyrazine skeleton, a pyridazine skeleton, a pyrimidine skeleton, a triazine skeleton, a purine skeleton, and derivatives thereof each of which contains the nitrogen atom in second bond portion 22; and (ii) a thiocarbonyl group which contains the sulfur atom in first bond portion 21. In this way, first molecular skeleton A1 is provided which has a hydrogen bonding property or a coordination bonding property to a metal atom and has tautomerism on the surface of the metal. In first structure 24, (i) the secondary amine which contains the nitrogen atom in second bond portion 22 easily captures active oxygen.

Specific examples of first structure 24 in first molecular skeleton A1 include structures represented by the following structural formulae.

First structure 24 which includes an imidazole skeleton and a thiocarbonyl group is, for example, a molecular structure represented by structural formula (1) below.

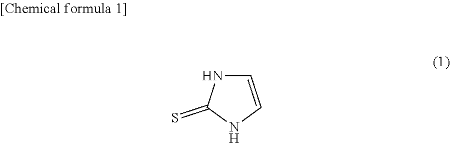

First structure 24 which includes a benzimidazole skeleton and a thiocarbonyl group is, for example, a molecular structure represented by structural formula (2) below.

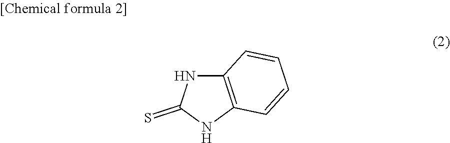

First structure 24 which includes a triazole skeleton and a thiocarbonyl group is, for example, a molecular structure represented by structural formula (3) below.

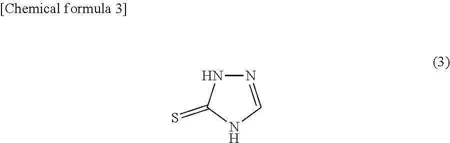

First structure 24 which includes a tetrazole skeleton and a thiocarbonyl group is, for example, a molecular structure represented by structural formula (4) below.

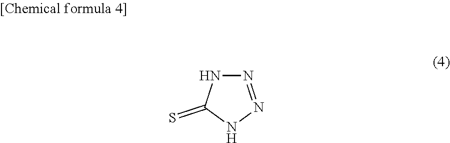

First structure 24 which includes a thiazole skeleton and a thiocarbonyl group is, for example, a molecular structure represented by structural formula (5) below.

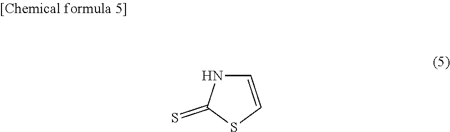

First structure 24 which includes a benzothiazole skeleton and a thiocarbonyl group is, for example, a molecular structure represented by structural formula (6) below.

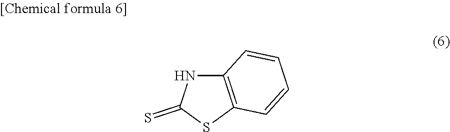

First structure 24 which includes a thiadiazole skeleton and a thiocarbonyl group is, for example, a molecular structure represented by structural formula (7) below.

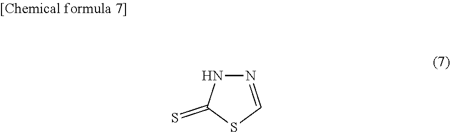

First structure 24 which includes an oxazole skeleton and a thiocarbonyl group is, for example, a molecular structure represented by structural formula (8) below.

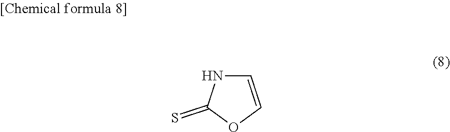

First structure 24 which includes a benzoxazole skeleton and a thiocarbonyl group is, for example, a molecular structure represented by structural formula (9) below.

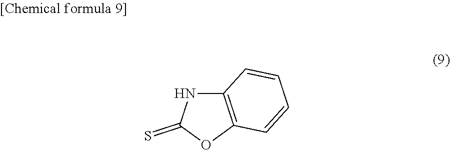

First structure 24 which includes an oxadiazole skeleton and a thiocarbonyl group is, for example, a molecular structure represented by structural formula (10) below.

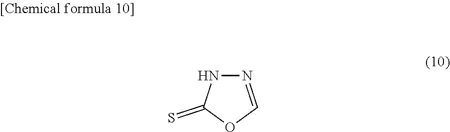

First structure 24 which includes a pyridine skeleton and a thiocarbonyl group is, for example, a molecular structure represented by any one of structural formulae (11-1) to (11-3) below.

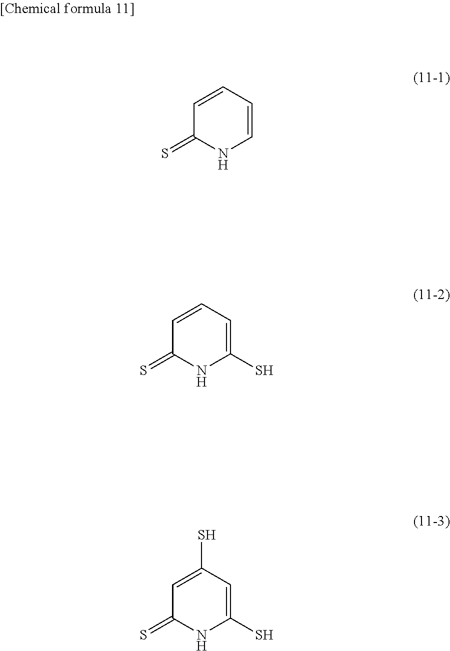 [SMILES: S=c1cccc[nH]1 ; S=c1cccc(S)[nH]1 ; S=c1cc(S)cc(S)[nH]1]

First structure 24 which includes a pyrimidine skeleton and a thiocarbonyl group is, for example, a molecular structure represented by any one of structural formulae (12-1) to (12-7) below.

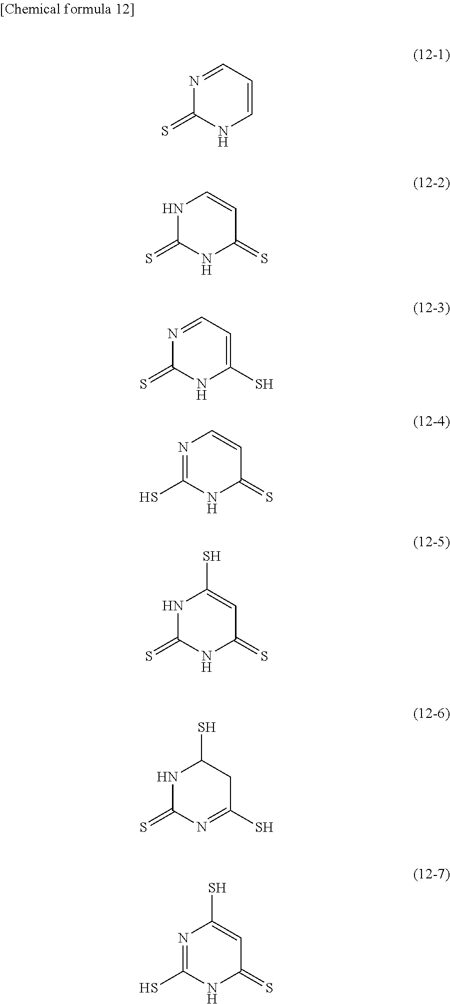

First structure 24 which includes a pyrazine skeleton and a thiocarbonyl group is, for example, a molecular structure represented by any one of structural formulae (13-1) and (13-2) below.

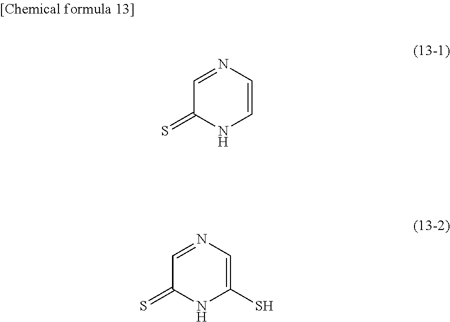 [SMILES: S=c1cncc[nH]1 ; S=c1cncc(S)[nH]1]

First structure 24 which includes a pyridazine skeleton and a thiocarbonyl group is, for example, a molecular structure represented by any one of structural formulae (14-1) to (14-3) below.

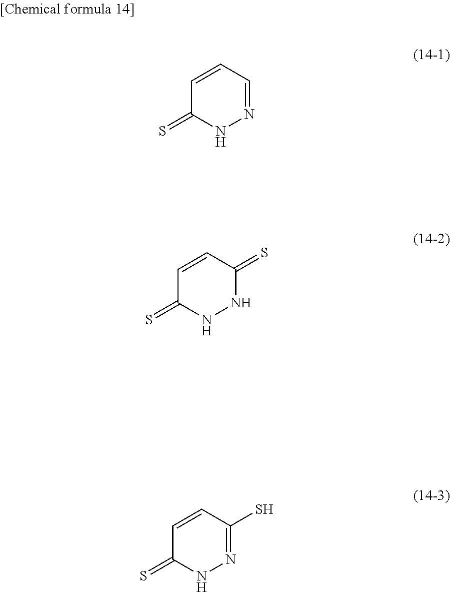 [SMILES: S=c1cccn[nH]1 ; S=c1ccc(=S)[nH][nH]1 ; S=c1ccc(S)n[nH]1]

First structure 24 which includes a triazine skeleton and a thiocarbonyl group is, for example, a molecular structure represented by any one of structural formulae (15-1) to (15-6) below.

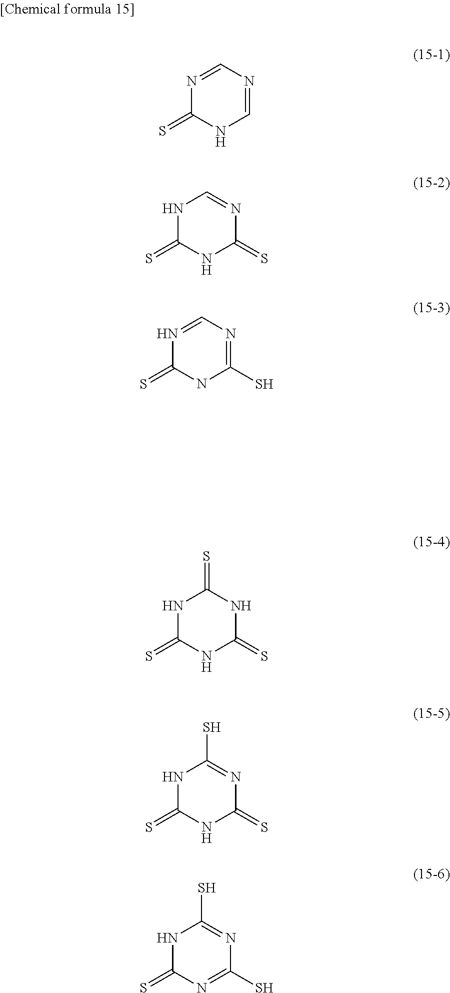 [SMILES: S=c1ncnc[nH]1 ; S=c1nc[nH]c(=S)[nH]1 ; S=c1ncnc(S)[nH]1 ; S=c1[nH]c(=S)[nH]c(=S)[nH]1 ; S=c1nc(S)[nH]c(=S)[nH]1 ; S=c1nc(S)nc(S)[nH]1]

First structure 24 which includes a purine skeleton and a thiocarbonyl group is, for example, a molecular structure represented by any one of structural formulae (16-1) to (16-12) below.

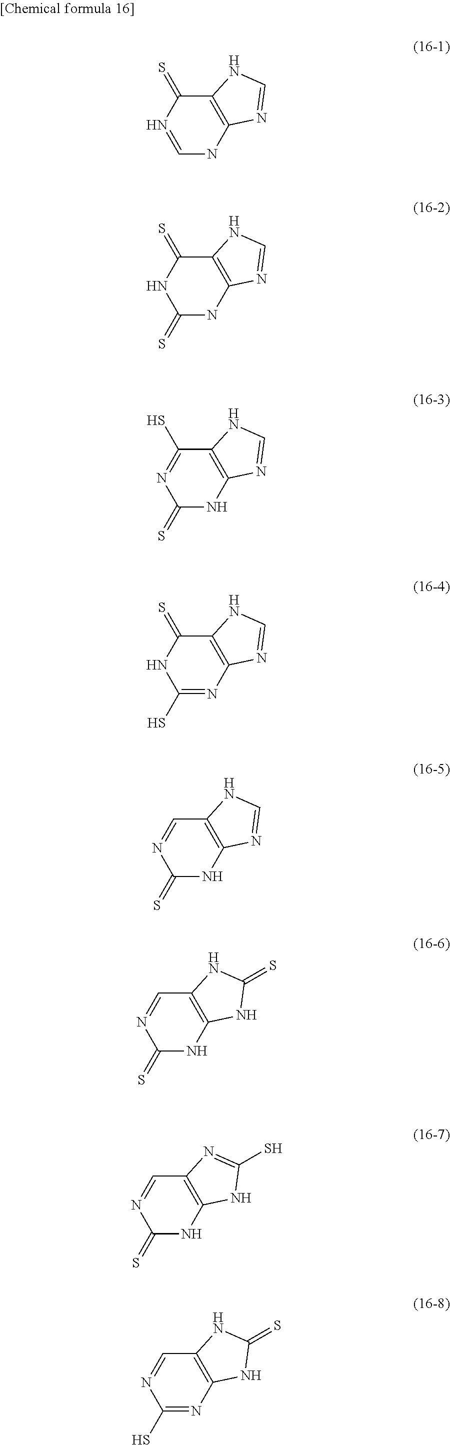

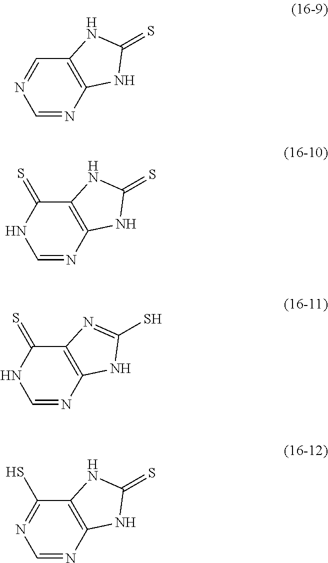 [SMILES: S=c1[nH]c2cncnc2[nH]1 ; S=c1[nH]c2nc[nH]c(=S)c2[nH]1 ; S=c1[nH]cnc2[nH]c(S)nc12 ; S=c1[nH]c2ncnc(S)c2[nH]1]

First structure 24 may be a molecular structure in which the molecular structure illustrated in each of the structural formulae described above is substituted with at least one substituent.

For the synthesis of first molecular skeleton A1, for example, a method of substituting the oxygen atom of a carbonyl with a sulfur atom, a method of converting a substituent of a nitrogen-containing heterocycle, a method using a cyclization reaction of a chain molecule containing a sulfur atom and a nitrogen atom, or the like can be utilized. As first molecular skeleton A1, a commercially available compound such as a compound which includes a nitrogen-containing heterocycle such as pyrimidine dithione or triazine dithione and a thiocarbonyl group, or a derivative thereof can also be used.

### [1-5-2. Main Chain B1]

Main chain B1 includes, for example, one or more selected from a group consisting of a methylene chain, a siloxane chain, a glycol chain, an aryl skeleton, an acene skeleton, and derivatives thereof. Functional organic molecule 17 includes main chain B1, and thus the interaction of main chains B1 facilitates the formation of coating 15 in which functional organic molecules 17 are arranged in a high density.

Main chain B1 is, for example, a general methylene-based organic molecule, an analogous species thereof (a compound, a chemical structure, or a derivative including one or more of a methylene chain, a siloxane chain, and a glycol chain), or the like.

Main chain B1 includes a methylene chain, and thus methylene chains can associate with each other intermolecularly to form a dense carbon chain of a supramolecular hydrocarbon chain, with the result that the stability of coating 15 can be enhanced. Main chain B1 includes a methylene chain, and thus coating 15 can be formed relatively rapidly.

When main chain B1 includes a siloxane chain, it is possible to form coating 15 having excellent heat resistance and weather resistance. Hence, for example, even when coating 15 is exposed to a relatively high temperature environment in the mounting process for the semiconductor element and the like, the effect of suppressing alteration and damage to coating 15 itself is achieved.

When main chain B1 includes a glycol chain, main chain B1 can easily be dissolved in a polar solvent such as water, and this is advantageous in forming coating 15.

For example, when heating conditions during wire bonding are set to a relatively high temperature, it is desirable to further enhance the heat resistance of coating 15 using functional organic molecule 17. In this case, main chain B1 may further include one or more of polar groups selected from a group consisting of a hydroxyl group, a carbonyl group, a thiocarbonyl group, a primary amine, a secondary amine, a tertiary amine, an ether, a sulfide, and an aromatic compound. In this way, it is possible to enhance the heat resistance of coating 15.

In particular, as the polar group, an amide group (for example, including a ketone and a secondary amine), an aromatic amide group (for example, including a ketone, a secondary amine, and an aromatic ring), an aromatic imide group (for example, including a ketone, a tertiary amine, and an aromatic ring), or a combination thereof may be used.

When main chain B1 which includes the polar group as described above is used, strong mutual bonding action (a stacking effect caused by a hydrogen bond or a London dispersion force) is exerted between main chains B1 of adjacent functional organic molecules 17 in coating 15, and thus coating 15 is strengthened. In other words, coating 15 is stably maintained even in a high temperature environment, and thus it is possible to enhance the heat resistance of coating 15.

Main chain B1 may be an aromatic compound such as a compound, a chemical structure, or a derivative which includes one or more selected from a group consisting of aryl skeletons (for example, phenyl, biphenyl, terphenyl, quaterphenyl, quinchyphenyl, and sexiphenyl), acene skeletons (for example, naphthalene, anthracene, naphthacene, and pentacene), a pyrene skeleton, a phenanthrene skeleton, a fluorene skeleton, and derivatives thereof.

When main chain B1 includes an aryl skeleton, as the number of aromatic rings increases, stronger mutual bonding action (a π-π stacking effect caused by a London dispersion force) is exerted between main chains B1, and thus the melting point of functional organic molecule 17 itself is increased, with the result that the thermal stability of coating 15 is significantly enhanced.

When main chain B1 includes an acene skeleton, as the number of aromatic rings increases, stronger mutual bonding action between main chains B1 is exerted by an aryl skeleton. In this way, it is possible to significantly reduce the permeability of a corrosive gas and water through coating 15. Furthermore, as the number of aromatic rings in an acene skeleton increases, the number of conjugated systems increases, and thus a light absorption spectrum shifts to the side of a longer wavelength. In this way, the light-absorbing effect of an acene skeleton (specifically, an ultraviolet light cutting effect) can suppress the alteration (for example, blackening caused by generation of silver oxide) of a metal such as silver with light absorption in a short wavelength region (ultraviolet region). This effect is noticeable in an acene skeleton, but an aryl skeleton also has the same effect.

Furthermore, when main chain B1 includes a pyrene skeleton, a phenanthrene skeleton, or a fluorene skeleton, in addition to the mutual bonding action of aromatic rings and the ultraviolet light cutting effect, the effect of utilizing the light energy for fluorescence or phosphorescence is strongly exerted.

### [1-5-3. Second Molecular Skeleton C1]

In order to enhance adhesion to the optical semiconductor element, a sealing resin, and the like, second molecular skeleton C1 is required to have a resin curing property or a resin curing acceleration property for a thermosetting or light curing resin. When second molecular skeleton C1 has the performance described above, second molecular skeleton C1 may be any one of a compound, a chemical structure, and a derivative which includes one or more of substituents.

Examples of second molecular skeleton C1 include compounds, chemical structures, and derivatives that include one or more of a compound including an antibody which is bonded to a specific molecule and a hydroxyl group, a compound including a carboxylic acid, a compound including an acid anhydride, a compound including a primary amine, a compound including a secondary amine, a compound including a tertiary amine, a compound including a quaternary ammonium salt, a compound including an amide group, a compound including a vinyl group, a compound including an imide group, a compound including a hydrazide group, a compound including an imine group, a compound including an amidine group, a compound including imidazole, a compound including triazole, and a compound including tetrazole. Second molecular skeleton C1 may be, for example, any one of a compound, a chemical structure, and a derivative which includes one or more selected from a group consisting of a hydroxyl group, a carboxylic acid, an acid anhydride, a primary amine, a secondary amine, a tertiary amine, an amide group, and a vinyl group. In a case where any one of these compounds, derivatives thereof, and the like is used as second molecular skeleton C1, when second molecular skeleton C1 makes contact with a curing resin, a bonding or curing reaction occurs, and thus second molecular skeleton C1 is bonded to the curing resin.

Hence, it is possible to enhance the adhesion of circuit substrate 18 to the sealing resin including the curing resin.

### [1-5-4. Specific Examples of Functional Organic Molecule]

Specific examples of functional organic molecule 17 will be described. The following specific examples are examples, and the molecular structure of functional organic molecule 17 is not limited to the following specific examples.

A first specific example of functional organic molecule 17 is a compound represented by structural formula (17) below. In structural formula (17), a state where first molecular skeleton A1 has first structure 24 is shown.

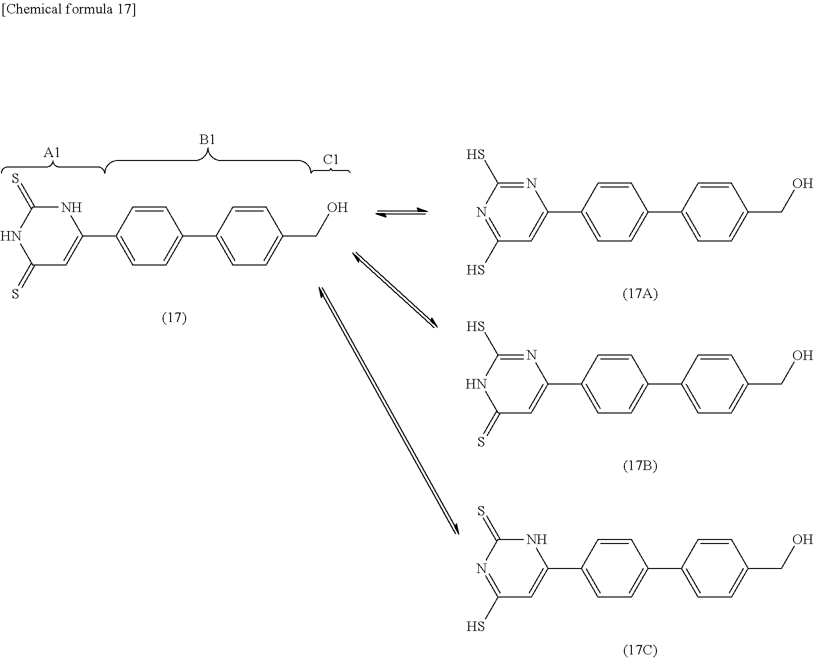

First molecular skeleton A1 (first structure 24) shown in structural formula (17) is pyrimidine dithione which includes a pyrimidine skeleton and two thiocarbonyl groups. Main chain B1 shown in structural formula (17) is formed by bonding an aryl skeleton (specifically, biphenyl) and a methylene chain in this order. Second molecular skeleton C1 shown in structural formula (17) includes a hydroxyl group.

In an example shown in structural formula (17), first structure 24 includes two first bond portions 21 and two second bond portions 22. Hence, first molecular skeleton A1 in the first specific example is isomerized between first structure 24 (structural formula (17) described above), second structure 23 (structural formula (17A) described above) in which two thiocarbonyl groups are changed into a thiol group, and second structure 23 (structural formula (17B) and structural formula (17C) described above) in which one thiocarbonyl group is changed into a thiol group.

A second specific example of functional organic molecule 17 is a compound represented by structural formula (18) below. In structural formula (18), a state where first molecular skeleton A1 has first structure 24 is shown.

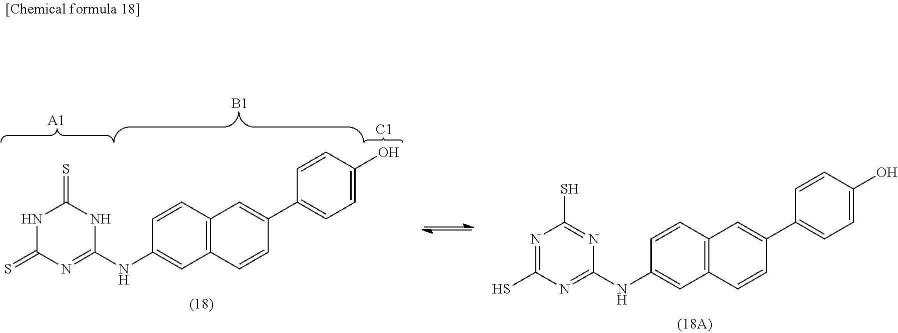

First molecular skeleton A1 (first structure 24) shown in structural formula (18) is triazine dithione which includes a triazine skeleton and two thiocarbonyl groups. Main chain B1 shown in structural formula (18) is formed by bonding a secondary amine, an acene skeleton (specifically, naphthalene), and an aryl skeleton (specifically, phenyl) in this order from the side of first molecular skeleton A1. Second molecular skeleton C1 shown in structural formula (18) includes a hydroxyl group.

First molecular skeleton A1 in the second specific example is isomerized between first structure 24 (structural formula (18) described above) and second structure 23 (structural formula (18A) described above) in which two thiocarbonyl groups are changed into a thiol group. Although not shown in the structural formula, first structure 24 shown in structural formula (18) is also isomerized to second structure 23 in which one thiocarbonyl group is changed into a thiol group as in the first specific example. The same is true for third to fifth specific examples which will be described below.

A third specific example of functional organic molecule 17 is a compound represented by structural formula (19) below. In structural formula (19), a state where first molecular skeleton A1 has first structure 24 is shown.

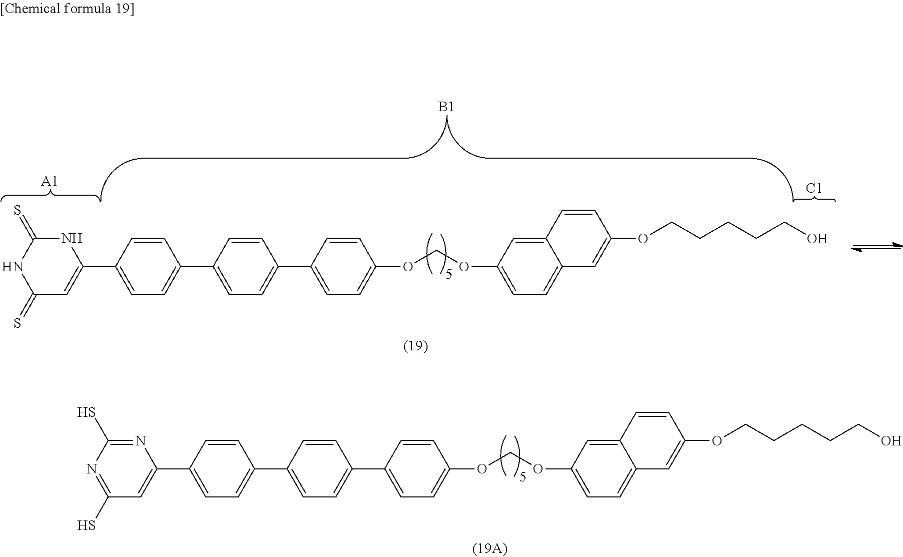

First molecular skeleton A1 (first structure 24) shown in structural formula (19) is pyrimidine dithione which includes a pyrimidine skeleton and two thiocarbonyl groups. Main chain B1 shown in structural formula (19) is formed by bonding an aryl skeleton (specifically, terphenyl), an ether, a methylene chain, an ether, an acene skeleton (specifically, naphthalene), an ether, and a methylene chain in this order from the side of first molecular skeleton A1. Second molecular skeleton C1 shown in structural formula (19) includes a hydroxyl group.

First molecular skeleton A1 in the third specific example is isomerized between first structure 24 (structural formula (19) described above) and second structure 23 (structural formula (19A) described above) in which two thiocarbonyl groups are changed into a thiol group.

A fourth specific example of functional organic molecule 17 is a compound represented by structural formula (20) below. In structural formula (20), a state where first molecular skeleton A1 has first structure 24 is shown.

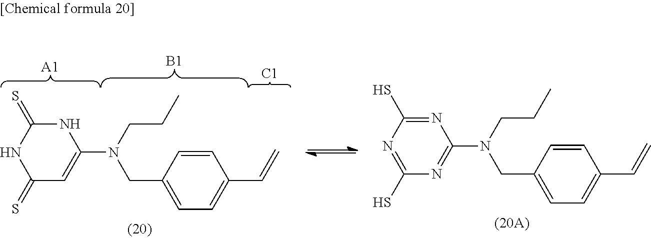

First molecular skeleton A1 (first structure 24) shown in structural formula (20) is triazine dithione which includes a triazine skeleton and two thiocarbonyl groups. Main chain B1 shown in structural formula (20) is formed by bonding a tertiary amine, a methylene chain, and an aryl skeleton (specifically, phenyl) in this order from the side of first molecular skeleton A1. Second molecular skeleton C1 shown in structural formula (20) includes a vinyl group.

First molecular skeleton A1 in the fourth specific example is isomerized between first structure 24 (structural formula (20) described above) and second structure 23 (structural formula (20A) described above) in which two thiocarbonyl groups are changed into a thiol group.

A fifth specific example of functional organic molecule 17 is a compound represented by structural formula (21) below. In structural formula (21), a state where first molecular skeleton A1 has first structure 24 is shown. Functional organic molecule 17 in the fifth specific example does not include main chain B1, and includes first molecular skeleton A1 and second molecular skeleton C1.

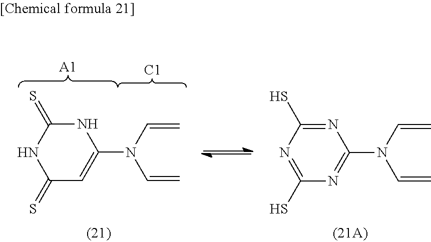

First molecular skeleton A1 (first structure 24) shown in structural formula (21) is triazine dithione which includes a triazine skeleton and two thiocarbonyl groups. Second molecular skeleton C1 shown in structural formula (21) includes a tertiary amine and two vinyl groups.

First molecular skeleton A1 in the fifth specific example is isomerized between first structure 24 (structural formula (21) described above) and second structure 23 (structural formula (21A) described above) in which two thiocarbonyl groups are changed into a thiol group.

Functional organic molecule 17 is any one of the first to fifth specific examples to be able to effectively enhance the performance of coating 15.

Functional organic molecule 17 may be a derivative in which the molecular structure in each of the specific examples is substituted with at least one substituent. The number of aromatic rings in main chain B1 and/or the number of carbon atoms in the methylene chain in each of the specific examples may be changed.

### [1-6. Surrounding Resin]

As shown in FIG. 2A, surrounding resin 19 serves as the reflector which reflects light emitted from the optical semiconductor element mounted on optical semiconductor element mounting region 20 toward the outside (upward in FIG. 2A and the like). Surrounding resin 19 is the bowl-shaped wall which surrounds, in a rectangular shape, optical semiconductor element mounting region 20 on which the optical semiconductor element is mounted when viewed from above. Surrounding resin 19 includes a base resin and the white pigment.

The white pigment is, for example, titanium oxide (TiO₂). In this way, it is possible to increase the reflectance of surrounding resin 19 for light. The white pigment may be a white pigment other than titanium oxide such as zinc oxide (ZnO), barium sulfate (BaSO₄), silicon oxide (SiO₂), zirconium oxide (ZrO₂), aluminum oxide (Al₂O₃), aluminum nitride (AlN), and the like.

Examples of the base resin include thermoplastic resins such polyphthalamide (PPA), liquid crystal polymer (LCP), as polycyclohexyl dimethylene terephthalate (PCT), unsaturated polyester (UP), and polypropylene (PP), and thermosetting resins such as an epoxy resin, a silicone resin, a polyimide resin, and an acrylic resin.

### [2. Features of Optical Semiconductor Device Package Component]

The features of optical semiconductor device package component 30 configured as described above and according to the present embodiment will then be described in detail. Optical semiconductor device package component 30 according to the present embodiment is used as, for example, a package component used in an optical semiconductor device. Optical semiconductor device package component 30 is used in the optical semiconductor device, and thus it is possible to effectively suppress a decrease in the performance of the optical semiconductor device. In particular, it is possible to effectively suppress shortening of the life of the optical semiconductor device caused by deterioration of metal film 14 due to active oxygen induced by high-power driving and/or long-term driving of the optical semiconductor device and active oxygen present in the atmosphere.

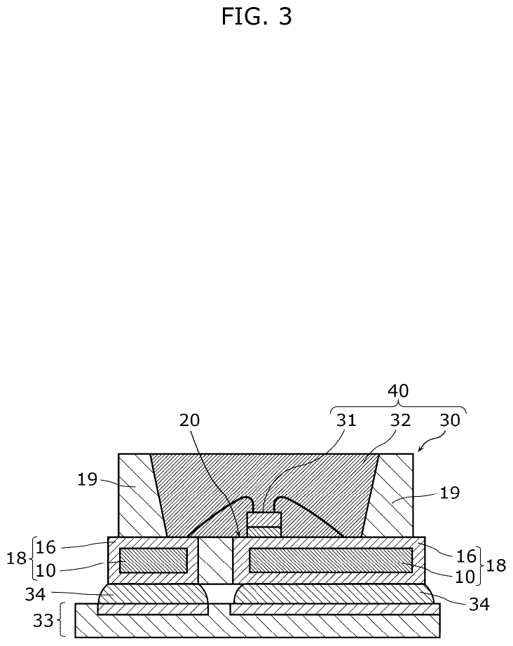

FIG. 3 is a cross-sectional view showing the configuration of optical semiconductor device 40 according to the present embodiment.

As shown in FIG. 3, optical semiconductor device 40 includes optical semiconductor device package component 30, optical semiconductor element 31, and sealing resin 32. Optical semiconductor device 40 is used, for example, by being bonded to mounting substrate 33 with solder 34.

Optical semiconductor element 31 is mounted, for example, on optical semiconductor element mounting region 20 of optical semiconductor device package component 30 by die bonding and wire bonding. A method for mounting optical semiconductor element 31 is not particularly limited, and for example, optical semiconductor element 31 may be flip-chip mounted on optical semiconductor element mounting region 20. Optical semiconductor element 31 is, for example, a light emitting element such as a light emitting diode (LED). Light emitted by the light emitting element is not limited to visible light, and invisible light such as ultraviolet or infrared light may be emitted.

An internal space surrounded by surrounding resin 19 on optical semiconductor element mounting region 20 of optical semiconductor device package component 30 is filled with sealing resin 32, and sealing resin 32 seals optical semiconductor element 31.

In optical semiconductor device 40, for example, by the influence of photocatalytic action caused by “heat”, “light”, and “titanium oxide serving as the white pigment in surrounding resin 19 which functions as the reflector” when optical semiconductor device 40 is driven for a long period of time, oxygen present in the atmosphere is turned into active oxygen (specifically, a superoxide anion), and the active oxygen turns silver which is an example of second metal 12 into silver oxide to turn its color black. Depending on the wavelength of light emitted by optical semiconductor element 31, oxygen present in the atmosphere is turned into active oxygen only by “light” and “heat”. Depending on the storage environment of optical semiconductor device 40, optical semiconductor device 40 is exposed to trace amounts of active oxygen present in the atmosphere (for example, a superoxide anion, a hydroxyl radical, hydrogen peroxide, chlorine dioxide, and the like) during long-term storage, thus silver which is an example of second metal 12 is gradually oxidized to turn black. When as described above, in optical semiconductor device 40, second metal 12 is discolored due to active oxygen, the reflectance of optical semiconductor element mounting region 20 is lowered, and thus the efficiency of light emission is lowered. Hence, the life of optical semiconductor device 40 is shortened. In some cases, optical semiconductor device 40 is not operated due to deterioration other than the discoloration of second metal 12, and the life of optical semiconductor device 40 is shortened. In the present embodiment, optical semiconductor device package component 30 is used in optical semiconductor device 40, and thus it is possible to suppress shortening of the life of optical semiconductor device 40.

### [2-1. Features of Metal Film]

As described with reference to FIG. 2B, optical semiconductor device package component 30 according to the present embodiment includes metal film 14 in which first metal 11, second metal 12, and third metal 13 are in contact in optical semiconductor element mounting region 20. A feature will first be described in which optical semiconductor device package component 30 includes metal film 14 to suppress shortening of the life of optical semiconductor device 40.

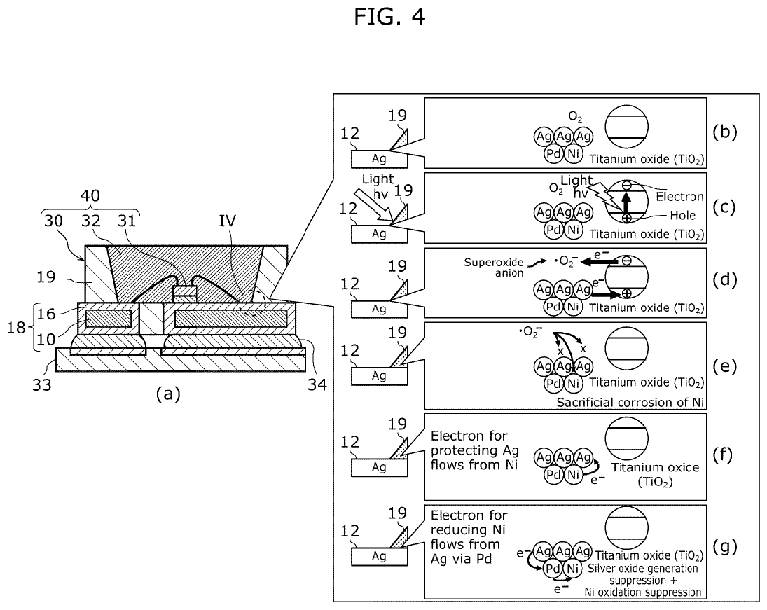

FIG. 4 is a diagram for illustrating suppression of shortening of the life of optical semiconductor device 40 which uses optical semiconductor device package component 30 according to the present embodiment. Even in the figure, as a state where optical semiconductor device package component 30 is used, optical semiconductor device 40 is shown which includes optical semiconductor device package component 30 and optical semiconductor element 31 mounted on optical semiconductor device package component 30. Part (a) in FIG. 4 is a cross-sectional view of optical semiconductor device 40 which is bonded to mounting substrate 33 with solder 34. Parts (b) to (g) are diagrams for illustrating a mechanism for suppressing, in region IV in part (a) in FIG. 4, generation of silver oxide in silver which is an example of second metal 12.

In circuit substrate 18 of optical semiconductor device package component 30 according to the present embodiment, a relationship between the standard electrode potentials of first metal 11, second metal 12, and third metal 13 (which are respectively referred to as the “first standard electrode potential”, the “second standard electrode potential”, and the “third standard electrode potential”) is first standard electrode potential<second standard electrode potential<third standard electrode potential. In optical semiconductor device 40, for example, by the influence of photocatalytic action caused by “heat”, “light”, and “titanium oxide serving as the white pigment in surrounding resin 19 which functions as the reflector” when optical semiconductor device 40 is driven for a long period of time, oxygen present in the atmosphere is turned into active oxygen (specifically, a superoxide anion) (parts (b) to (d) in FIG. 4). For the issue in which the active oxygen turns silver into silver oxide to turn its color black and thereby shortens the life of optical semiconductor device 40, in optical semiconductor device package component 30 according to the present embodiment, first metal 11 (in the present embodiment, nickel or a nickel alloy) having a standard electrode potential lower than second metal 12 (in the present embodiment, silver or a silver alloy) is in contact with second metal 12, and thus oxidation of silver is suppressed by the sacrificial corrosion effect caused by the reaction of active oxygen permeating second metal 12 with first metal 11 and the corrosion of first metal 11 (part (e) in FIG. 4). In other words, when nickel is oxidized by the superoxide anion due to the sacrificial corrosion of nickel (part (e) in FIG. 4), electrons flow from the nickel to silver (part (f) in FIG. 4). In this way, a phenomenon is suppressed in which silver is protected by the electrons flowing into silver, and silver is oxidized into silver oxide (Ag₂O).

As shown in part (g) in FIG. 4, third metal 13 (in the present embodiment, palladium or a palladium alloy) having the third standard electrode potential plays a role in attracting electrons which excessively enter second metal 12 having the second standard electrode potential and transmitting them to first metal 11. Hence, electron circulation is formed in which excessive electrons in silver generated when first metal 11 donates electrons to second metal 12 by the sacrificial corrosion action are transmitted to third metal 13, and are returned to first metal 11. In this way, the blackening (generation of silver oxide) of silver which is an example of second metal 12 caused by active oxygen is suppressed while the oxidation progress of first metal 11 caused by the sacrificial corrosion effect of first metal 11 is being suppressed, with the result that a decrease in reflectance is suppressed.

In addition to the effect of inactivation of active oxygen, metal film 14 can suppress diffusion of the metal of base member 10. Specifically, first metal 11 is present as the base of second metal 12 (in the present embodiment, silver or a silver alloy) which serves as a reflective coating in optical semiconductor element mounting region 20. Hence, even when optical semiconductor device 40 is driven for a long period of time, diffusion of a large amount of metal (for example, copper) of base member 10 to the surface of second metal 12 is blocked, and thus it is possible to suppress a decrease in the reflectance of second metal 12.

### [2-2. Feature of Coating]

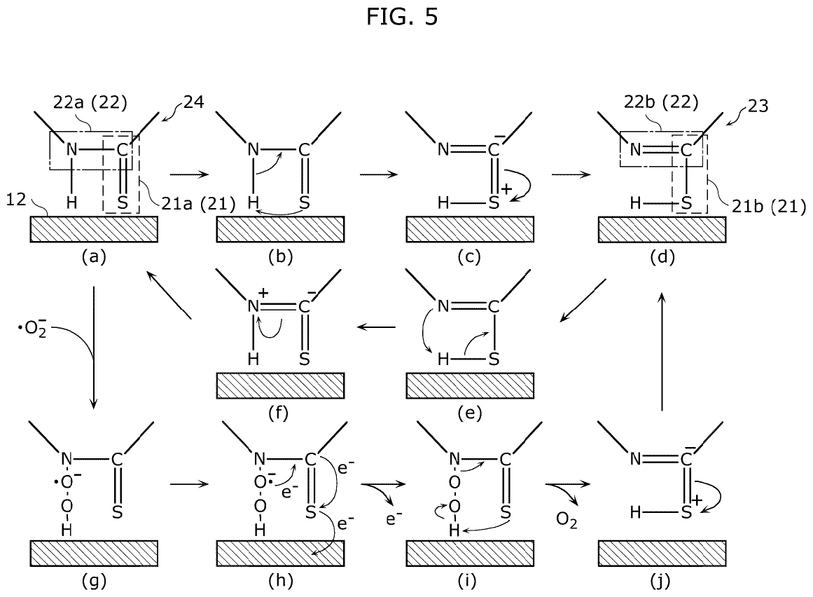

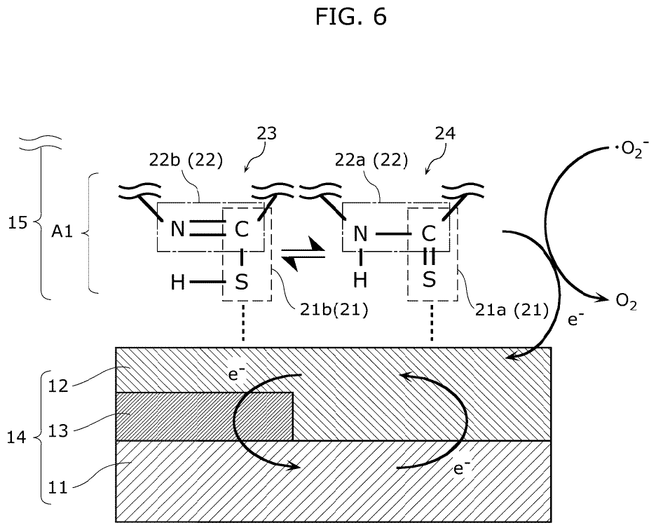

In optical semiconductor device package component 30, coating 15 which coats metal film 14 is formed, and thus it is also possible to suppress shortening of the life of optical semiconductor device 40. Specifically, functional organic molecule 17 included in coating 15 inactivates active oxygen. Coating 15 is formed on metal film 14, and thus the function of inactivation of active oxygen performed by functional organic molecule 17 is enhanced. The feature of coating 15 will be described in detail below with reference to FIGS. 5 and 6.

FIG. 5 is a diagram for illustrating action for scavenging the radical of active oxygen caused by first molecular skeleton A1 in functional organic molecule 17 in the present embodiment. FIG. 6 is a diagram for illustrating inactivation of active oxygen caused by coating 15 and metal film 14 in the present embodiment.

As described above, functional organic molecule 17 included in coating 15 includes first molecular skeleton A1 which has tautomerism where first structure 24 and second structure 23 are isomerized to each other.

Specifically, as shown in part (a) in FIG. 5, in first structure 24 of first molecular skeleton A1, the sulfur atom and the carbon atom in first bond portion 21 are double bonded, and the nitrogen atom and the carbon atom in second bond portion 22 are single bonded. In first structure 24, the nitrogen atom in second bond portion 22 is bonded to the hydrogen atom. In first structure 24, the sulfur atom in first bond portion 21 is not bonded to the hydrogen atom. In the following description, for distinction, first bond portion 21 in first structure 24 may be referred to as first bond portion 21a, and second bond portion 22 in first structure 24 may be referred to as second bond portion 22a. First bond portion 21 in second structure 23 may be referred to as first bond portion 21b, and second bond portion 22 in second structure 23 may be referred to as second bond portion 22b.

As sequentially shown in parts (a), (b), (c), and (d) in FIG. 5, first structure 24 shown in part (a) in FIG. 5 is isomerized to second structure 23 in such a way that in first bond portion 21a and second bond portion 22a, transfer of an electron (e⁻) and the hydrogen atom (H) occurs, and the hydrogen atom bonded to the nitrogen atom in second bond portion 22a is removed from the nitrogen atom and is added to the sulfur atom in first bond portion 21a. As shown in part (d) in FIG. 5, the transfer of the electron brings second structure 23 into a state where the sulfur atom and the carbon atom in first bond portion 21b are single bonded, and the nitrogen atom and the carbon atom in second bond portion 22b are double bonded. The sulfur atom in first bond portion 21b is bonded to the hydrogen atom. The nitrogen atom in second bond portion 22b is not bonded to the hydrogen atom.

By contrast, as sequentially shown in parts (d), (e), (f), and (a) in FIG. 5, second structure 23 shown in part (d) in FIG. 5 is isomerized to first structure 24 in such a way that in first bond portion 21b and second bond portion 22b, transfer of the electron and the hydrogen atom occurs, and the hydrogen atom bonded to the sulfur atom in first bond portion 21b is removed from the sulfur atom and is added to the nitrogen atom in second bond portion 22b. As shown in part (a) in FIG. 5, the transfer of the electron brings first structure 24 into a state where the sulfur atom and the carbon atom in first bond portion 21a are double bonded, and the nitrogen atom and the carbon atom in second bond portion 22a are single bonded. As described above, first structure 24 and second structure 23 can be isomerized to each other, and thus first molecular skeleton A1 has tautomerism. Although in an example shown in FIG. 5, in the isomerization, the hydrogen atom is removed and the removed hydrogen atom is added by the reaction in the molecule, that is, the hydrogen atom is rearranged in the molecule, the hydrogen atom may be added and removed by a reaction with another molecule, ion or the like.

The reaction caused by tautomerism in first molecular skeleton A1 reversibly occurs on second metal 12, and thus the effect of inactivating active oxygen is achieved for the issue in which active oxygen deteriorates second metal 12 to shorten the life of optical semiconductor device 40.

Specifically, as shown in parts (a), (g), (h), (i), (j), and (d) and reaction formula (22) below, active oxygen is captured to be inactivated. As shown in parts (a) and (g) in FIG. 5, active oxygen (·O₂⁻) is first captured between the nitrogen atom in second bond portion 22a of first molecular skeleton A1 in functional organic molecule 17 and the hydrogen atom bonded to the nitrogen atom as shown in reaction formula (22) below. Then, as shown in parts (h), (i), (j), and (d) in FIG. 5, active oxygen is inactivated by the action for scavenging the radical of active oxygen caused by flow of the electron in active oxygen into second metal 12 via the carbon atom and the sulfur atom in first bond portion 21. Then, the captured active oxygen is turned into inactivated oxygen and is removed, and the electron is transferred, with the result that first molecular skeleton A1 has second structure 23 shown in part (d) in FIG. 5. Furthermore, by tautomerism in first molecular skeleton A1, as described above, the reaction proceeds in an order indicated by parts (d), (e), (f), and (a) in FIG. 5, and first molecular skeleton A1 returns to first structure 24. When this mechanism is used, first structure 24 for capturing active oxygen is reproduced many times, and thus the function of inactivating active oxygen is unlikely to be lowered.

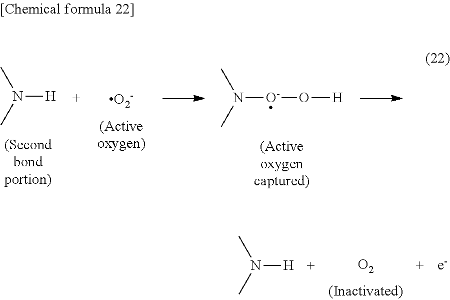

In this way, blackening of silver which is an example of second metal 12 caused by active oxygen is suppressed, and thus a decrease in the reflectance of optical semiconductor device 40 is effectively suppressed.

Such active oxygen causes a radical chain reaction not only on second metal 12 but also on surrounding resin 19. In this way, the decomposition of surrounding resin 19 is accelerated, yellowing and deterioration of surrounding resin 19 are affected, and thus a decrease in the luminous flux of optical semiconductor device 40 and a reduction in the life thereof are caused. In the vicinity of surrounding resin 19 (for example, below surrounding resin 19 and in an area around surrounding resin 19 when viewed from above), second metal 12 and coating 15 are present, and thus active oxygen (·O₂⁻) is captured by functional organic molecule 17 to be inactivated, with the result that it is possible to suppress yellowing and deterioration of surrounding resin 19. Consequently, it is possible to extend the life of optical semiconductor device 40.

Furthermore, as shown in FIG. 6, coating 15 including functional organic molecule 17 is formed on metal film 14 of a multilayer structure. In metal film 14 of a multilayer structure, as described with reference to FIG. 5, the surface of second metal 12 is unlikely to be oxidized by the sacrificial corrosion and electron circulation caused by the standard electrode potential. Hence, when coating 15 receives the electron from active oxygen and transmits the electron to second metal 12, the surface resistance of second metal 12 is unlikely to be increased, and thus the electron can be rapidly transferred to second metal 12. Then, the electron transfer and electron circulation in metal film 14 of a multilayer structure are added, and thus metal film 14 is stabilized. For example, the electron circulation in which the electron transmitted from coating 15 to second metal 12 is attracted by third metal 13 and is transmitted from third metal 13 to first metal 11 suppresses the oxidation progress of first metal 11 caused by the sacrificial corrosion effect of first metal 11. The electron transmitted from coating 15 to second metal 12 is attracted by third metal 13, and thus the electron received by coating 15 from active oxygen is easily transmitted to second metal 12. In this way, it is possible to further enhance the effect of suppressing blackening caused by oxidation of second metal 12 due to active oxygen.

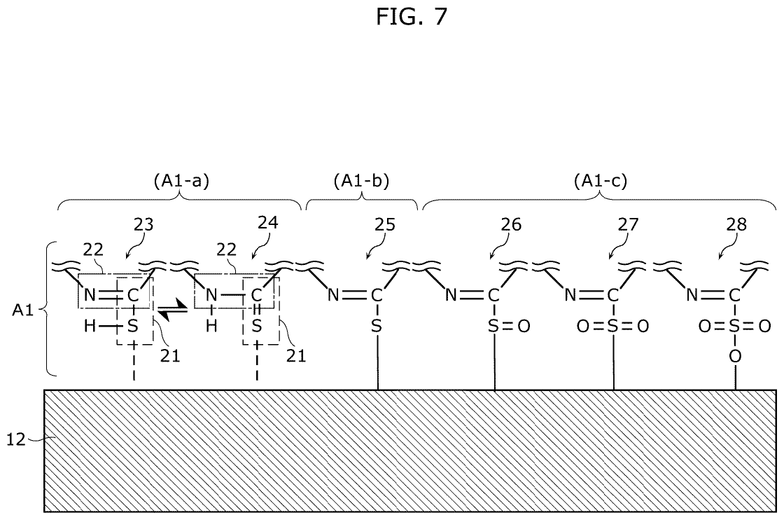

The forms of existence of the sulfur atom in first bond portion 21 for providing tautomerism to first molecular skeleton A1 will then be described. FIG. 7 is a diagram for comparing the forms of existence of the sulfur atoms on second metal 12.

In a case where first molecular skeleton A1 can be isomerized between first structure 24 and second structure 23 (part (A1-a) in FIG. 7), when in X-ray photoelectron spectroscopy (XPS), for example, monochromatic Al Kα (1486.6 eV) is used as an X-ray source, a peak where the bond energy of an XPS spectrum obtained at a photoelectron extraction angle of 45° is 160.9 to 162.9 eV, for example, 161.9 eV in S2p, a peak where the bond energy is 396.5 to 400.5 eV, for example, 398.5 eV in N1s, and a peak where the bond energy is 366.2 to 370.2 eV, for example, 368.2 eV in Ag3d are confirmed.

When the peaks in the XPS spectrum as described above are detected, the sulfur atom in first bond portion 21 and the nitrogen atom in second bond portion 22 are present in a state where the electron density is high. Furthermore, the nitrogen atom in second bond portion 22 is present as the nitrogen atom of the secondary amine (—NH—C—) in first structure 24 or the nitrogen atom of the imine group (—N═C—) in second structure 23. The sulfur atom in first bond portion 21 is disposed on second metal 12 without the intervention of another atom, for example, the sulfur atom is coordinately bonded to second metal 12 such as silver by an unshared electron pair, and on second metal 12, the sulfur atom is present as the sulfur atom of the thiocarbonyl group in first structure 24 (>C═S . . . Ag) or the sulfur atom of the thiol group in second structure 23 (—SH . . . Ag). Since the peaks in the in the XPS spectrum described above are detected, the sulfur atom in first bond portion 21 is said not to be the sulfur atom of a metal sulfide (—S-Metal, for example, —S—Ag) or disulfide (—S—S—) which cannot take a structure having tautomerism. In other words, first molecular skeleton A1 can be confirmed to be a structure which has tautomerism where the hydrogen atom can be transferred between the sulfur atom in first bond portion 21 and the nitrogen atom in second bond portion 22. In such a case, as described previously, the nitrogen atom in second bond portion 22 can receive the electron of active oxygen and transmit the electron to second metal 12, and thus the effect (radical scavenging capacity) of inactivating active oxygen is obtained.

The existence ratio (atomic percent: at %) of the total of sulfur atoms in first bond portions 21 of first structure 24 and second structure 23 having tautomerism as described above to all sulfur atoms on second metal 12 is, for example, greater than or equal to 40 at % and less than or equal to 100 at %, and may be greater than or equal to 80 at % and less than or equal to 100 at %. In this way, the effect of inactivating active oxygen is obtained more easily. Specifically, the total of sulfur atoms in first bond portions 21 is the total of the sulfur atom of the thiocarbonyl group (>C═S . . . Ag) in first structure 24 and the sulfur atom of the thiol group (—SH . . . Ag) in second structure 23.

The existence of first structure 24 and second structure 23 can also be confirmed by an infrared absorption spectrum (IR spectrum), a Raman spectrum, or the like.

On the other hand, in the case of a structure including a sulfur atom or a nitrogen atom with a low electron density as in the case of a negative oxidation number, for example, in the sulfur atom of a sulfur oxide (—SOₓ) as in structure 26, 27, or 28 shown in part (A1-c) in FIG. 7, a peak is detected which is derived from the sulfur oxide (—SOₓ) with the bond energy of the XPS spectrum being 164.2 to 170.8 eV in S2p. For example, although not shown in the figure, in the nitrogen atom of a nitrogen oxide (—NOₓ), a peak is detected which is derived from the nitrogen oxide (—NOₓ) with the bond energy of the XPS spectrum being 403.1 to 408.1 eV in Nis. In the case of the structure as described above including the sulfur oxide or the like bonded to second metal 12, isomerization cannot be achieved, and thus tautomerism is not provided. Hence, when the structure as described above is included in coating 15, the effect of inactivating active oxygen (radical scavenging capacity) is lowered. Therefore, a smaller number of structures as described above may be provided in coating 15.

The existence ratio (atomic percent: at %) of the sulfur atom of the sulfur oxide (—SOₓ) with a low electron density as described above to all sulfur atoms on second metal 12 is, for example, greater than or equal to 0 at % and less than or equal to 60 at %, and may be greater than or equal to 0 at % and less than or equal to 20 at %. In this way, the effect of inactivating active oxygen is obtained more easily.

Furthermore, in a case where as in structure 25 shown in part (A1-b) in FIG. 7, even when the electron density of the sulfur atom or the nitrogen atom is high, the sulfur atom is present as a metal sulfide (—S-Metal, for example, —S—Ag), a peak is detected which is derived from the metal sulfide (—S-Metal, for example, —S—Ag) with the bond energy of the XPS spectrum being 159.9 to 11.9 eV, for example, 160.9 eV in S2p. In the case of the structure including the metal sulfide of second metal 12 as described above, the sulfur atom is covalently or ionically bonded to second metal 12, and thus it is difficult to achieve isomerization to provide tautomerism. Hence, when the structure as described above is included in coating 15, the effect of inactivating active oxygen (radical scavenging capacity) is lowered. Therefore, a smaller number of structures as described above may be provided in coating 15.

The existence ratio (atomic percent: at %) of the sulfur atom of the metal sulfide (—S-Metal) as described above to all sulfur atoms on second metal 12 is, for example, greater than or equal to 0 at % and less than or equal to 60 at %, and may be greater than or equal to 0 at % and less than or equal to 20 at %. In this way, the effect of inactivating active oxygen is obtained more easily.

### [2-3. Overview]

As described above, optical semiconductor device package component 30 is a package component which includes circuit substrate 18. Circuit substrate 18 includes first metal 11, second metal 12 stacked on the upper surface of first metal 11, and coating 15 which coats the upper surface of second metal 12 and includes functional organic molecule 17. Functional organic molecule 17 includes first molecular skeleton A1 that includes first bond portion 21 in which the sulfur atom having a negative oxidation number is bonded to the carbon atom and second bond portion 22 in which the nitrogen atom having a negative oxidation number is bonded to the carbon atom. First molecular skeleton A1 has tautomerism where in coating 15, first structure 24 and second structure 23 are isomerized to each other.

In this way, in first structure 24, the nitrogen atom in second bond portion 22 is bonded to the hydrogen atom, and active oxygen can be captured in this bond. The electron of the captured active oxygen is passed through the sulfur atom in first bond portion 21, and is transmitted to second metal 12. In this way, it is possible to inactivate active oxygen. By tautomerism in first molecular skeleton A1, the captured active oxygen is removed, and thus first structure 24 can be isomerized to second structure 23, and second structure 23 can be returned again to first structure 24. First metal 11 which has a standard electrode potential lower than second metal 12 is present, and thus by the sacrificial corrosion effect of first bond portion 21, second metal 12 is unlikely to be oxidized, and the surface resistance of second metal 12 is unlikely to be increased. Hence, the electron of the active oxygen captured by first molecular skeleton A1 is easily transmitted to second metal 12, and thus the effect of inactivating active oxygen caused by first molecular skeleton A1 can be enhanced. Therefore, with coating 15, it is possible to effectively inactivate active oxygen generated, for example, when optical semiconductor device 40 is driven for a long period of time.

Circuit substrate 18 further includes third metal 13 which is formed on parts of the upper surface of first metal 11 and between first metal 11 and second metal 12.

In this way, the electron which flows into second metal 12 when first metal 11 is subjected to sacrificial corrosion caused by active oxygen is attracted by third metal 13 having a standard electrode potential higher than second metal 12 and is transmitted to first metal 11, and thus it is possible to suppress the oxidation progress of first metal 11. Hence, the sacrificial corrosion effect of first metal 11 can be enhanced. The electron which is transmitted from the active oxygen captured by first molecular skeleton A1 to second metal 12 is also attracted by third metal 13. Hence, the electron of the active oxygen captured by first molecular skeleton A1 is easily transmitted to second metal 12, and thus it is possible to enhance the effect of inactivating active oxygen caused by first molecular skeleton A1. Therefore, with coating 15, it is possible to effectively inactivate active oxygen generated, for example, when optical semiconductor device 40 is driven for a long period of time.

Circuit substrate 18 further includes base member 10, and first metal 11 is formed on base member 10.

In this way, even when a metal such as copper or a copper alloy which is easily processed as the lead frame of circuit substrate 18 and has excellent thermal conductivity and electrical conductivity and is easily diffused to gold and silver that are homogeneous elements is used for base member 10, first metal 11 suppresses the diffusion of the metal of base member 10 to second metal 12, and thus it is possible to suppress a decrease in the reflectance of second metal 12. The diffusion of the metal of base member 10 is suppressed, and thus the metal of base member 10 diffused to second metal 12 is unlikely to be oxidized, and thus the surface resistance of second metal 12 is unlikely to be increased. Hence, the electron of the active oxygen captured by first molecular skeleton A1 is easily transmitted to second metal 12, and thus it is possible to enhance the effect of inactivating active oxygen caused by first molecular skeleton A1.

With the configuration described above, in optical semiconductor device package component 30 according to the present embodiment, deterioration such as the oxidation of second metal 12 caused by active oxygen is suppressed, and thus it is possible to suppress shortening of the life of optical semiconductor device 40. For example, even when optical semiconductor device 40 is driven for a long period of time, the original property of silver having a high reflectance is not impaired, and thus sufficient light emission brightness for optical semiconductor device 40 is obtained. For example, the function of suppressing oxidation of sliver plating is enhanced, and thus even when the thickness of silver plating is reduced as compared with a conventional case, satisfactory mounting characteristics are obtained, with the result that conservation of resources of noble metals used in optical semiconductor device 40 can be achieved.

### [3. Method for Manufacturing Optical Semiconductor Device Package Component]

Optical semiconductor device package component 30 according to the present embodiment will then be specifically described together with an overall manufacturing process therefor.

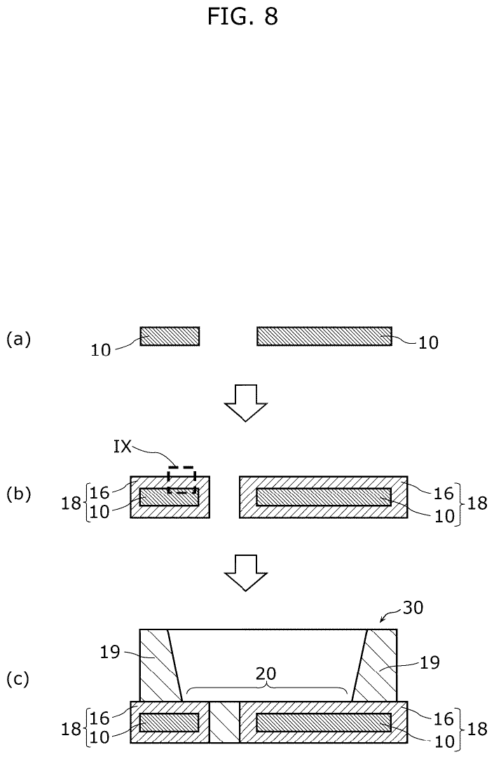

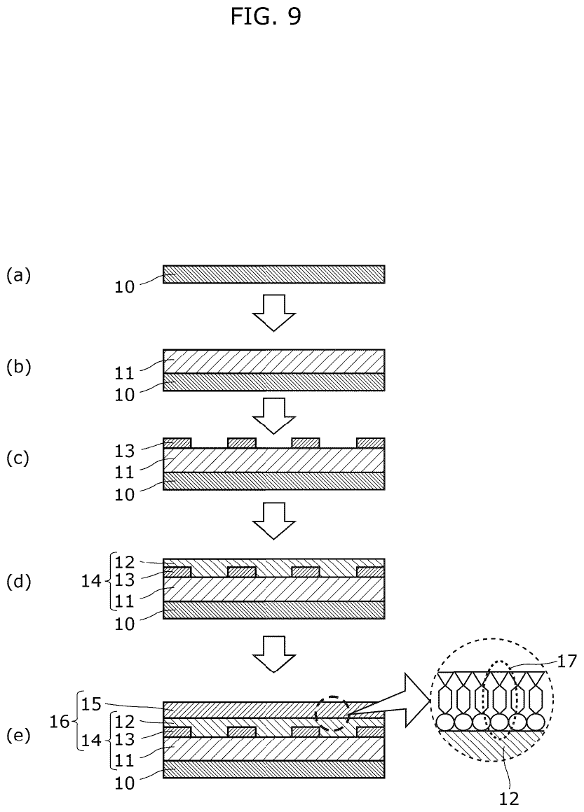

FIG. 8 is a diagram showing a manufacturing process for optical semiconductor device package component 30 according to the present embodiment. FIG. 9 is a diagram showing a manufacturing process for composite film 16 in optical semiconductor device package component 30 according to the present embodiment. In FIG. 9, region IX in part (b) in FIG. 8 is enlarged, and the manufacturing process for composite film 16 is shown. Part (e) in FIG. 9 corresponds to an enlarged view of region IX in part (b) in FIG. 8.

As shown in FIG. 8, the base member of copper or a copper alloy which is an example of base member 10 is first prepared (step of preparing the base member; part (a) in FIG. 8). Then, composite film 16 is formed on at least a part of the surface of base member 10 (step of forming the composite film; part (b) in FIG. 8). For example, the multilayer structure of composite film 16 is formed on at least the upper surface of base member 10. In an example shown in FIG. 8, the multilayer structure of composite film 16 is formed on the entire surface of base member 10.

Specifically, as shown in FIG. 9, on at least a part of the surface of base member 10, a plating layer of nickel or a nickel alloy is formed as first metal 11 (step of forming the first metal; part (b) in FIG. 9). Then, on parts of the upper surface of first metal 11, plating of palladium or a palladium alloy which is an example of third metal 13 is formed (step of forming the third metal; part (c) in FIG. 9). Furthermore, plating of silver or a silver alloy which is an example of second metal 12 is formed to cover at least a part of the exposed surface of each of first metal 11 and third metal 13 (step of forming the second metal; part (d) in FIG. 9). In this way, metal film 14 is formed.

Furthermore, on a part of the upper surface or the entire upper surface of second metal 12, coating 15 including functional organic molecule 17 is formed by self-assembly of functional organic molecule 17 (step of forming the coating including the functional organic molecule; part (e) in FIG. 9). Through the steps as described above, composite film 16 is formed on base member 10. Although the formation of composite film 16 on the upper side of base member 10 has been described with reference to FIG. 9, composite film 16 may be formed on the lateral sides and the lower side of base member 10 as on the upper side.

With reference back to FIG. 8, on a part of the surface of composite film 16, surrounding resin 19 including the white pigment is then formed (step of forming the surrounding resin; part (c) in FIG. 8). Surrounding resin 19 is formed on, for example, a part of the surface of coating 15 in composite film 16. When in composite film 16, a region where coating 15 is not formed is provided on a part of the upper surface of second metal 12, surrounding resin 19 may be formed on the upper surface of second metal 12 in the region.

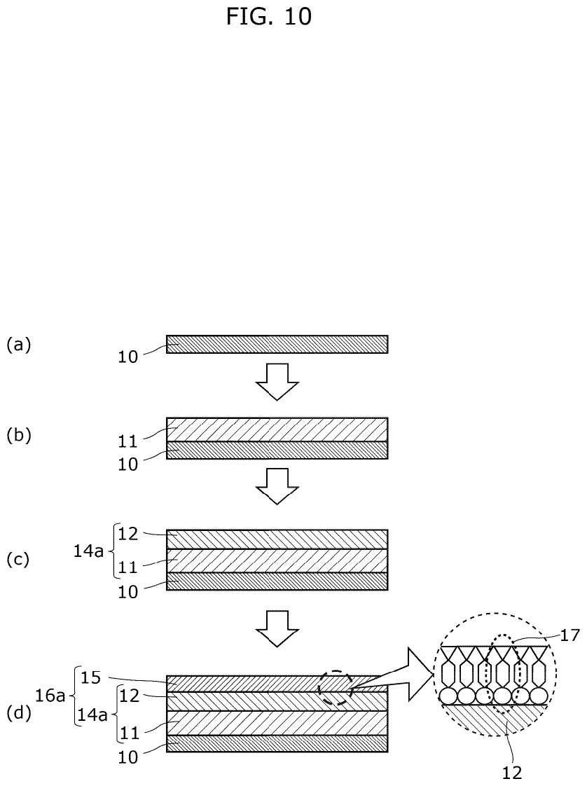

Composite film 16 does not need to include third metal 13. FIG. 10 is a diagram showing a manufacturing process for another composite film 16a in optical semiconductor device package component 30 according to the present embodiment. In FIG. 10, the same region of optical semiconductor device package component 30 as in FIG. 9 is enlarged and shown. When as shown in FIG. 10, composite film 16a is formed which does not include third metal 13 and includes first metal 11, second metal 12 and coating 15, a step of manufacturing the third metal is omitted, a step of manufacturing the second metal (part (c) in FIG. 10) is performed immediately after a step of manufacturing the first metal (part (b) in FIG. 10). In the step of manufacturing the second metal shown in part (c) in FIG. 10, on at least a part of the upper surface of first metal 11, plating of silver or a silver alloy which is an example of second metal 12 is formed. In this way, metal film 14a is formed. Thereafter, a step of forming the coating including the functional organic molecule (part (d) in FIG. 10) is performed. Through the steps as described above, composite film 16a is formed on base member 10. Even in optical semiconductor device package component 30 which includes composite film 16a as described above, coating 15 including functional organic molecule 17 is formed on second metal 12, and thus it is possible to achieve the effect of suppress shortening of the life of optical semiconductor device 40.

The step of forming the first metal, the step of forming the second metal, the step of forming the third metal, the step of forming the coating including the functional organic molecule, and the step of forming the surrounding resin will be described in detail below.

### [3-1. Step of Forming First Metal]

As shown in part (b) in FIG. 9 and part (b) in FIG. 10, in the step of forming the first metal, on at least a part of the surface of the base member of copper or a copper alloy which is an example of base member 10 prepared in the step of preparing the base member, as first metal 11, for example, plating of nickel or a nickel alloy is applied. In the present embodiment, first metal 11 is formed on the entire upper surface of base member 10.

### [3-2. Step of Forming Third Metal]

As shown in part (c) in FIG. 9, in the step of forming the third metal, on parts of the upper surface of first metal 11, as third metal 13, for example, plating of palladium or a palladium alloy is applied. In this way, third metal 13 is disposed between second metal 12 to be formed later and first metal 11 which has already been formed.

### [3-3. Step of Forming Second Metal]

As shown in part (d) in FIG. 9, in the step of forming the second metal for manufacturing metal film 14, on parts of the surface of the base member of nickel or a nickel alloy which is an example of first metal 11 prepared in the step of forming the first metal, as second metal 12, for example, silver plating or silver alloy plating is applied. In the present embodiment, second metal 12 is formed to cover at least a part of the exposed surface of each of first metal 11 and third metal 13 prepared in the step of forming the first metal and in the step of forming the third metal. In this way, metal film 14 of a multilayer structure is obtained.

As shown in part (c) in FIG. 10, in a step of forming the second metal for manufacturing metal film 14a, on at least a part of the surface of the base member of nickel or a nickel alloy which is an example of first metal 11 prepared in the step of forming the first metal, as second metal 12, for example, silver plating or silver alloy plating is applied. In the present embodiment, second metal 12 is formed on the entire upper surface of first metal 11. In this way, metal film 14a of a multilayer structure is obtained.

Second metal 12 is provided, and thus not only the effect of enhancing the reflectance but also the effect of enhancing die bonding, wire bonding, flip chip bonding or solderability is achieved.

### [3-4. Step of Forming Coating Including Functional Organic Molecule]

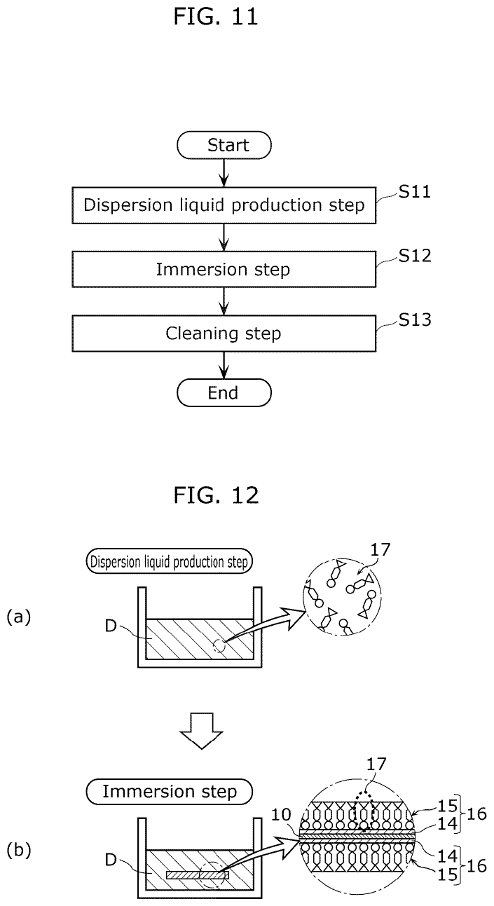

The step of forming the coating including the functional organic molecule (part (e) in FIG. 9 and part (d) in FIG. 10) will be described in detail with reference to FIGS. 11 and 12. FIG. 11 is a flowchart of the step of forming the coating including the functional organic molecule in the present embodiment. FIG. 12 is a diagram for illustrating the step of forming the coating including the functional organic molecule in the present embodiment.

As shown in FIG. 11, the step of forming the coating including the functional organic molecule includes a dispersion liquid preparation sub-step which is also referred to as a dispersion liquid production step (S11), a film formation sub-step which is also referred to as an immersion step (S12), and a cleaning sub-step which is also referred to as a cleaning step (S13), and these sub-steps are performed in this order.

### [3-4-1. Dispersion Liquid Preparation Sub-Step]

Here, a case where coating 15 including functional organic molecule 17 is formed using functional organic molecule 17 will be described.

In the dispersion liquid preparation sub-step, as shown in part (a) in FIG. 12, functional organic molecule 17 is dispersed in a predetermined solvent, and thus dispersion liquid D is prepared. As the solvent, at least one of an organic solvent and water can be utilized. When water is used as the solvent, in order to obtain the dispersibility of functional organic molecule 17, as necessary, an anionic, cationic or nonionic surfactant may be added. Furthermore, in order to stabilize functional organic molecule 17, a pH buffer of a boric acid, a phosphoric acid, an organic acid, or the like and an antioxidant may be added.

In order to enhance the ability to inactivate active oxygen in coating 15, the pH of dispersion liquid D of functional organic molecule 17 may be set less than or equal to the acid dissociation constant pka of first bond portion 21 in first molecular skeleton A1 of functional organic molecule 17.

When dispersion liquid D of the pH as described above is used, a hydrogen atom (proton) is added to the sulfur atom in first bond portion 21 of first molecular skeleton A1 or the nitrogen atom in second bond portion 22, a covalent bond or an ionic bond between second metal 12 and the sulfur atom in the first bond portion is unlikely to be formed, and the sulfur atom in first bond portion 21 is easily covalently bonded to second metal 12. In this way, on second metal 12, first molecular skeleton A1 can be turned into a structure having tautomerism, and thus the radical scavenging capacity of inactivating active oxygen is obtained.

On the other hand, dispersion liquid D of a pH higher than the acid dissociation constant pka of first bond portion 21 in first molecular skeleton A1 of functional organic molecule 17 is used, and thus it is possible to form functional organic molecule 17 on second metal 12, but a percentage of first molecular skeleton A1 which is turned into a metal sulfide (—S-Metal, for example, —S—Ag) that cannot be turned into a structure having tautomerism on second metal 12 is easily increased.

### [3-4-2. Film Formation Sub-Step]

Then, in the film formation sub-step, as shown in part (b) in FIG. 12, a predetermined surface of metal film 14 of a multilayer structure formed on base member 10 is immersed in dispersion liquid D prepared in the dispersion liquid preparation sub-step. In dispersion liquid D, each functional organic molecule 17 is at an energy level with relatively high Gibbs free energy, and each single molecule moves randomly (so-called Brownian motion) due to an interaction in a repulsive direction. Hence, when metal film 14 of a multilayer structure formed on base member 10 is immersed in dispersion liquid D, functional organic molecule 17 is microscopically bonded to metal film 14 of a multilayer structure by first molecular skeleton A1 to attempt to shift to a more stable state.

In the shift to the stable state, as enlarged and schematically shown in part (b) in FIG. 12, microscopically, while functional organic molecules 17 are bonding the first molecular skeletons to the surface of metal film 14 of a multilayer structure, functional organic molecules 17 are stabilized in a state where main chains B1 and second molecular skeletons C1 are aligned in the same order, with the result that functional organic molecules 17 take a self-assembled form as a single molecular film.

A self-assembled film is formed according to the above principle, and when lifted from the dispersion liquid, composite film 16 is obtained which is a structure where coating 15 including the functional organic molecules is formed on metal film 14 of a multilayer structure.

Although part (b) in FIG. 12 shows, as an example, a case where coating 15 is formed on all the surfaces of metal film 14 of a multilayer structure, for example, a pattern mask which has an opening in a predetermined shape may be previously provided on the surface of metal film 14 of a multilayer structure, and thus coating 15 may be formed only on a part of the surface of metal film 14 of a multilayer structure which corresponds to the opening.

Although the immersion method utilizing the dispersion liquid is illustrated, a method for forming coating 15 is not limited to this method. For example, coating 15 of the same may be formed using another method such as spraying.

In the film formation sub-step, the film may be formed while cathodic electrolysis is being performed so that the surface of metal film 14 is activated. In the film formation sub-step, functional organic molecules 17 may be electrically formed as a film by cathodic electrolysis.

### [3-4-3. Cleaning Sub-Step]

In the cleaning sub-step, on composite film 16 obtained from dispersion liquid D, at least one of an organic solvent or water is used as a cleaning medium to perform cleaning treatment for removing extra functional organic molecules 17. Since functional organic molecule 17 which is not directly bonded to metal film 14 of a multilayer structure with first molecular skeleton A1 cannot transmit the electron of the captured active oxygen to second metal 12, the cleaning sub-step is performed to remove functional organic molecules 17 which are not bonded to metal film 14 of a multilayer structure, with the result that it is possible to enhance the effect of inactivating active oxygen with coating 15.

Through the sub-steps described above, the step of forming the coating including the functional organic molecule is completed. Although in the above description of the sub-steps, the example where coating 15 is formed on the surface of metal film 14 is shown, the same sub-steps are used to be able to form coating 15 on the surface of metal film 14a.

### [3-5. Step of Forming Surrounding Resin]

In the step of forming the surrounding resin, as shown in part (c) in FIG. 8, on a part of the surface of composite film 16, surrounding resin 19 is formed to surround the outer periphery of optical semiconductor element mounting region 20. Surrounding resin 19 is provided, and thus the function of an insulator between optical semiconductor element mounting region 20 and a wire bonding area and the function of a reflector for light emitted from the light emitting element are achieved.

Through the steps described above, optical semiconductor device package component 30 is manufactured.

Optical semiconductor device 40 can be manufactured by die bonding optical semiconductor element 31 on optical semiconductor element mounting region 20 of optical semiconductor device package component 30, wire bonding optical semiconductor element 31 and circuit substrate 18, and then filling the internal space surrounded by surrounding resin 19 with sealing resin 32.

### Other Embodiments

Although the circuit substrate, the optical semiconductor device package component, and the optical semiconductor device according to the present invention and the method for manufacturing the optical semiconductor device package component have been described based on the embodiment, the present invention is not limited to the embodiment described above. Embodiments obtained by performing various types of variations conceived by a person skilled in the art on the present embodiment and other embodiments established by combining some constituent elements in the embodiment are also included in the scope of the present invention as long as the embodiments do not depart from the spirit of the present invention.

For example, although optical semiconductor device package component 30 according to the embodiment described above includes a pair of circuit substrates 18 which are separate from each other, the present invention is not limited to this configuration. Optical semiconductor device package component 30 may include one circuit substrate 18 or three or more circuit substrates 18.

Although in optical semiconductor device package component 30 according to the embodiment described above, as optical semiconductor element 31, an LED chip is mounted, the present invention is not limited to this configuration. Optical semiconductor element 31 may be a light receiving element. In optical semiconductor device package component 30, as a plurality of optical semiconductor elements 31, both a light emitting element and a light receiving element may be mounted.

Although circuit substrate 18 according to the embodiment described above is used for optical semiconductor device package component 30, the present invention is not limited to this configuration. Circuit substrate 18 may be used as a multilayer structure for an electronic component other than optical semiconductor device package component 30. For example, the multilayer structure as described above may be used for a sensor member. In this way, the deterioration of the sensor member in long-term storage, cleaning, or the like of the sensor member is suppressed, and thus it is possible to suppress, for example, a decrease in the molecular recognition performance of the sensor member.

Examples of the multilayer structure, the package component, and the optical semiconductor device described based on the above embodiment will be described below.

A multilayer structure according to a first aspect of the present disclosure includes: a first metal that has a first standard electrode potential; a second metal that is stacked on an upper surface of the first metal and has a second standard electrode potential higher than the first standard electrode potential; and a coating that coats an upper surface of the second metal and includes a functional organic molecule, the functional organic molecule includes a first molecular skeleton that includes: a first bond portion in which a sulfur atom having a negative oxidation number is bonded to a carbon atom; and a second bond portion in which a nitrogen atom having a negative oxidation number is bonded to a carbon atom, and in the coating, the first molecular skeleton has tautomerism where a first structure in which the nitrogen atom is bonded to a hydrogen atom and a second structure in which the sulfur atom is bonded to a hydrogen atom are isomerized to each other by addition and removal of a hydrogen atom.

For example, a multilayer structure according to a second aspect of the present disclosure is the multilayer structure according to the first aspect, and further includes: a third metal that is disposed on a part of the upper surface of the first metal and has a third standard electrode potential higher than the first standard electrode potential and the second standard electrode potential, and the third metal is disposed between the first metal and the second metal in a stacking direction.

For example, a multilayer structure according to a third aspect of the present disclosure is the multilayer structure according to the first or second aspect, and the third metal includes gold, a gold alloy, or a platinum group element-containing metal.

For example, a multilayer structure according to a fourth aspect of the present disclosure is the multilayer structure according to any one of the first to third aspects, the third metal includes the platinum group element-containing metal, and the platinum group element-containing metal is palladium, a palladium alloy, platinum, or a platinum alloy.

For example, a multilayer structure according to a fifth aspect of the present disclosure is the multilayer structure according to any one of the first to fourth aspects, and the first metal includes nickel or a nickel alloy.

For example, a multilayer structure according to a sixth aspect of the present disclosure is the multilayer structure according to any one of the first to fifth aspects, and the second metal includes silver or a silver alloy.

For example, a multilayer structure according to a seventh aspect of the present disclosure is the multilayer structure according to any one of the first to sixth aspects, and the oxidation number of the sulfur atom is −2.

For example, a multilayer structure according to an eighth aspect of the present disclosure is the multilayer structure according to any one of the first to seventh aspects, and the first structure includes a thiocarbonyl group containing the sulfur atom.

For example, a multilayer structure according to a ninth aspect of the present disclosure is the multilayer structure according to any one of the first to eighth aspects, and the oxidation number of the nitrogen atom is −3.

For example, a multilayer structure according to a tenth aspect of the present disclosure is the multilayer structure according to any one of the first to ninth aspects, and the first structure includes a secondary amine containing the nitrogen atom.

For example, a multilayer structure according to an eleventh aspect of the present disclosure is the multilayer structure according to any one of the first to tenth aspects, and the first molecular skeleton includes a nitrogen-containing heterocycle that contains the nitrogen atom.

For example, a multilayer structure according to a twelfth aspect of the present disclosure is the multilayer structure according to any one of the first to eleventh aspects, and the first structure includes: (i) one or more selected from a group consisting of an imidazole skeleton, a benzimidazole skeleton, a triazole skeleton, a tetrazole skeleton, a thiazole skeleton, a benzothiazole skeleton, a thiadiazole skeleton, an oxazole skeleton, a benzoxazole skeleton, an oxadiazole skeleton, a pyridine skeleton, a pyrimidine skeleton, a pyrazine skeleton, a pyridazine skeleton, a triazine skeleton, a purine skeleton, and derivatives thereof each of which contains the nitrogen atom; and (ii) a thiocarbonyl group that contains the sulfur atom.

For example, a multilayer structure according to a thirteenth aspect of the present disclosure is the multilayer structure according to any one of the first to twelfth aspects, and the functional organic molecule further includes a main chain, the first molecular skeleton is bonded to the main chain, and the main chain includes one or more selected from a group consisting of a methylene chain, a siloxane chain, a glycol chain, an aryl skeleton, an acene skeleton, and derivatives thereof.

For example, a multilayer structure according to a fourteenth aspect of the present disclosure is the multilayer structure according to any one of the first to thirteenth aspects, the functional organic molecule further includes a second molecular skeleton that has a resin curing property or a resin curing acceleration property, and the second molecular skeleton includes one or more selected from a group consisting of a hydroxyl group, a carboxylic acid, an acid anhydride, a primary amine, a secondary amine, a tertiary amine, an amide group, and a vinyl group.

For example, a multilayer structure according to a fifteenth aspect of the present disclosure is the multilayer structure according to any one of the first to fourteenth aspects, and further includes a base member, and the first metal is disposed on the base member.

A package component according to a sixteenth aspect of the present disclosure is a package component for mounting an optical semiconductor element, the package component includes: a circuit substrate; and a wall that is disposed on the circuit substrate, surrounds an outer periphery of a region on the circuit substrate on which the optical semiconductor element is mounted, and includes a white pigment, and the circuit substrate is the multilayer structure according to any one of the first to fifteenth aspects.

For example, a package component according to a seventeenth aspect of the present disclosure is the package component according to a sixteenth aspect, and the white pigment is titanium oxide.

An optical semiconductor device according to an eighteenth aspect of the present disclosure includes: an optical semiconductor element; and the package component according to the sixteenth aspect or the seventeenth aspect on which the optical semiconductor element is mounted.

### INDUSTRIAL APPLICABILITY

The present invention is useful for a circuit substrate (multilayer structure) and an optical semiconductor device package component used in electronic components, and is particularly suitable for a circuit substrate (multilayer structure) and an optical semiconductor device package component which can suppress a decrease in the efficiency of light emission in the long-term driving of an optical semiconductor device.

1. A multilayer structure comprising:
a first metal that has a first standard electrode potential;
a second metal that is stacked on an upper surface of the first metal and has a second standard electrode potential higher than the first standard electrode potential; and
a coating that coats an upper surface of the second metal and includes a functional organic molecule,
wherein the functional organic molecule includes a first molecular skeleton that includes:
a first bond portion in which a sulfur atom having a negative oxidation number is bonded to a carbon atom; and
a second bond portion in which a nitrogen atom having a negative oxidation number is bonded to a carbon atom, and
in the coating, the first molecular skeleton has tautomerism where a first structure in which the nitrogen atom is bonded to a hydrogen atom and a second structure in which the sulfur atom is bonded to a hydrogen atom are isomerized to each other by addition and removal of a hydrogen atom.

2. The multilayer structure according to claim 1, further comprising:
a third metal that is disposed on a part of the upper surface of the first metal and has a third standard electrode potential higher than the first standard electrode potential and the second standard electrode potential,
wherein the third metal is disposed between the first metal and the second metal in a stacking direction.

3. The multilayer structure according to claim 2,
wherein the third metal includes gold, a gold alloy, or a platinum group element-containing metal.

4. The multilayer structure according to claim 3,
wherein the third metal includes the platinum group element-containing metal, and
the platinum group element-containing metal is palladium, a palladium alloy, platinum, or a platinum alloy.

5. The multilayer structure according to claim 1,
wherein the first metal includes nickel or a nickel alloy.

6. The multilayer structure according to claim 1,
wherein the second metal includes silver or a silver alloy.

7. The multilayer structure according to claim 1,
wherein the oxidation number of the sulfur atom is −2.

8. The multilayer structure according to claim 1,
wherein the first structure includes a thiocarbonyl group containing the sulfur atom.

9. The multilayer structure according to claim 1,
wherein the oxidation number of the nitrogen atom is −3.

10. The multilayer structure according to claim 1,
wherein the first structure includes a secondary amine containing the nitrogen atom.

11. The multilayer structure according to claim 1,
wherein the first molecular skeleton includes a nitrogen-containing heterocycle that contains the nitrogen atom.

12. The multilayer structure according to claim 1,
wherein the first structure includes:
(i) one or more selected from a group consisting of an imidazole skeleton, a benzimidazole skeleton, a triazole skeleton, a tetrazole skeleton, a thiazole skeleton, a benzothiazole skeleton, a thiadiazole skeleton, an oxazole skeleton, a benzoxazole skeleton, an oxadiazole skeleton, a pyridine skeleton, a pyrimidine skeleton, a pyrazine skeleton, a pyridazine skeleton, a triazine skeleton, a purine skeleton, and derivatives thereof each of which contains the nitrogen atom; and
(ii) a thiocarbonyl group that contains the sulfur atom.

13. The multilayer structure according to claim 1,
wherein the functional organic molecule further includes a main chain,
the first molecular skeleton is bonded to the main chain, and
the main chain includes one or more selected from a group consisting of a methylene chain, a siloxane chain, a glycol chain, an aryl skeleton, an acene skeleton, and derivatives thereof.

14. The multilayer structure according to claim 1,
wherein the functional organic molecule further includes a second molecular skeleton that has a resin curing property or a resin curing acceleration property, and
the second molecular skeleton includes one or more selected from a group consisting of a hydroxyl group, a carboxylic acid, an acid anhydride, a primary amine, a secondary amine, a tertiary amine, an amide group, and a vinyl group.

15. The multilayer structure according to claim 1, further comprising:
a base member,
wherein the first metal is disposed on the base member.

16. A package component for mounting an optical semiconductor element, the package component comprising:
a circuit substrate; and
a wall that is disposed on the circuit substrate, surrounds an outer periphery of a region on the circuit substrate on which the optical semiconductor element is mounted, and includes a white pigment,
wherein the circuit substrate is the multilayer structure according to claim 1.

17. The package component according to claim 16,
wherein the white pigment is titanium oxide.

18. An optical semiconductor device comprising:
an optical semiconductor element; and
the package component according to claim 16 on which the optical semiconductor element is mounted.
